(19) United States
(12) Patent Application Publication
(10) Pub. No.: US 2025/0218871 A1
(43) Pub. Date: Jul. 3, 2025

(54) EXPANDING DEVICE, SEMICONDUCTOR CHIP MANUFACTURING METHOD, AND SEMICONDUCTOR CHIP

(71) Applicant: YAMAHA HATSUDOKI KABUSHIKI KAISHA, Iwata-shi, Shizuoka (JP)

(72) Inventor: Yoshikuni SUZUKI, Iwata-shi (JP)

(73) Assignee: YAMAHA HATSUDOKI KABUSHIKI KAISHA, Iwata-shi, Shizuoka (JP)

(21) Appl. No.: 18/848,472

(22) PCT Filed: Apr. 27, 2022
(86) PCT No.: PCT/JP2022/019177

§ 371 Date: Sep. 18, 2024

(51) Int. Cl. H01L 21/78; H01L 21/67; H01L 21/68; H01L 21/683

(52) U.S. Cl. CPC H01L 21/78; H01L 21/67092; H01L 21/67109; H01L 21/67132; H01L 21/67178; H01L 21/68; H01L 21/6836

(57) ABSTRACT

An expanding device includes an expander, a cooler, a squeegee unit, and a movement mechanism. The expander, at least one of the cooler or a heater, and the squeegee unit are linearly aligned in a plan view.

### CROSS-REFERENCE TO RELATED APPLICATION

This application is a National Stage of International Patent Application No. PCT/JP2022/019177, filed Apr. 27, 2022, the entire content of which is incorporated herein by reference.

### BACKGROUND

### Technical Field

The present disclosure relates to an expanding device, a semiconductor chip manufacturing method, and a semiconductor chip, and more particularly, it relates to an expanding device including an expander to divide a wafer into a plurality of semiconductor chips, a semiconductor chip manufacturing method, and a semiconductor chip.

### Background Art

Conventionally, an expanding device including an expander to divide a wafer into a plurality of semiconductor chips is known. Such an expanding device is disclosed in Japanese Patent No. 6298635, for example.

Japanese Patent No. 6298635 discloses a dividing device (expanding device) including an expander to divide a wafer into a plurality of chips. The dividing device includes a linear movement mechanism, a conveying unit with an arm, a cassette stage, the expander, and a cooling box.

The linear movement mechanism disclosed in Japanese Patent No. 6298635 is a movement mechanism that extends in a horizontal direction perpendicular to a direction in which the expander and the cooling box are aligned. The linear movement mechanism linearly moves the conveying unit with an arm in the horizontal direction perpendicular to the direction in which the expander and the cooling box are aligned. The conveying unit with an arm includes an arm including a multi-jointed link, and a holder. The conveying unit with an arm drives the arm including the multi-jointed link to change the position and posture of the holder in order to hold a ring frame surrounding the wafer attached to an expandable sheet. A wafer is supplied to the cassette stage. The cooling box cools the expandable sheet to which the wafer is attached. The expander expands the cooled expandable sheet to divide the wafer into the plurality of chips.

In the dividing device disclosed in Japanese Patent No. 6298635, the conveying unit with an arm that has been moved to the cassette stage by the linear movement mechanism holds the wafer supplied to the cassette stage, and then is moved to the cooling box by the linear movement mechanism to supply the wafer into the cooling box. In the dividing device, the cooled wafer in the cooling box is held by the conveying unit with an arm, and then the conveying unit with an arm conveys the wafer to the expander in which the wafer is divided.

### SUMMARY

Although not clearly described in Japanese Patent No. 6298635, in a dividing device as described in Japanese Patent No. 6298635, a squeegee unit may be provided to divide a wafer that has not been divided during expansion after the expandable sheet is expanded by the expander in addition to dividing the wafer into a plurality of chips by expanding the expandable sheet by the expander. In such a case, the squeegee unit divides the wafer that has not been divided by locally pressing a portion of the expandable sheet that corresponds to the wafer after the expander expands the expandable sheet.

When the squeegee unit is provided in the dividing device as described above, the wafer can be supplied to the squeegee unit by the linear movement mechanism and the conveying unit with an arm when the squeegee unit is arranged within a range in which the wafer can be supplied by the linear movement mechanism and the conveying unit with an arm. However, it is necessary to move the conveying unit with an arm by the linear movement mechanism and to drive the arm of the conveying unit with an arm to change the position and posture of the holder of the conveying unit with an arm, and thus the structure of the movement mechanism that supplies the wafer to the squeegee unit becomes complex. Thus, in the dividing device including the squeegee unit as described above, the movement mechanism that supplies the wafer between a plurality of devices such as the expander and the squeegee unit is conceivably complex. Therefore, in the dividing device (expanding device) including the squeegee unit as described above, it is desired to simplify the structure of the movement mechanism that supplies the wafer between a plurality of devices such as the expander and the squeegee unit.

Accordingly, the present disclosure provides an expanding device, a semiconductor chip manufacturing method, and a semiconductor chip that each enable a simple structure of a movement mechanism that supplies a wafer between a plurality of devices such as an expander and a squeegee unit.

An expanding device according to a first aspect of the present disclosure includes an expander to expand an elastic sheet member to divide a wafer into a plurality of semiconductor chips along a dividing line, at least one of a cooler to cool the sheet member before the sheet member is expanded by the expander or a heater to heat and shrink the sheet member expanded by the expander while maintaining a gap between the plurality of semiconductor chips, a squeegee unit to locally press the wafer after the expander expands the sheet member to divide the wafer into the plurality of semiconductor chips, and a movement mechanism to supply the wafer to the expander, at least one of the cooler or the heater, and the squeegee unit. The expander, at least one of the cooler or the heater, and the squeegee unit are linearly aligned in a plan view.

As described above, the expanding device according to the first aspect of the present disclosure includes the movement mechanism to supply the wafer to the expander, at least one of the cooler or the heater, and the squeegee unit in the plan view. In the plan view, the expander, at least one of the cooler or the heater, and the squeegee unit are linearly aligned. Accordingly, the wafer is supplied to the squeegee unit, the expander, and at least one of the cooler or the heater that are linearly aligned, using the movement mechanism such that a mechanism that conveys the wafer to the squeegee unit, the expander, and at least one of the cooler or the heater can be achieved by using one linear movement mechanism, and thus the structure of a movement mechanism that supplies the wafer between a plurality of devices such as the expander and the squeegee unit can be simplified.

The expanding device according to the first aspect preferably includes both the cooler and the heater, the expander is preferably below the heater, the cooler and the expander below the heater are preferably linearly aligned in the plan view, the squeegee unit is preferably in a straight line with the cooler and the expander in a direction in which the cooler and the expander are aligned in the plan view, and the movement mechanism is preferably operable to supply the wafer to the cooler, the expander, and the squeegee unit that are linearly aligned in the plan view. Accordingly, the expander is arranged below the heater such that an increase in the size of the expanding device in a horizontal direction can be reduced or prevented as compared with a case in which the expander is deviated from the heater in the horizonal direction. Furthermore, the wafer is supplied using the movement mechanism such that a mechanism that conveys the wafer to the squeegee unit, the expander, and the cooler can be achieved by using one linear movement mechanism, and thus the structure of the movement mechanism that supplies the wafer between a plurality of devices such as the expander and the squeegee unit can be simplified. Consequently, an increase in the size of the expanding device can be reduced or prevented, and the structure of the movement mechanism that supplies the wafer between a plurality of devices such as the expander and the squeegee unit can be simplified.

The expanding device according to the first aspect preferably includes both the cooler and the heater, the expander preferably includes an expanding ring having a ring shape to expand the sheet member to divide the wafer along the dividing line, the squeegee unit is preferably inside an inner circumferential surface of the expanding ring, the cooler and the heater are preferably linearly aligned in the plan view, the squeegee unit is preferably in a straight line with the cooler in a direction in which the cooler and the heater are aligned in the plan view, and the movement mechanism is preferably operable to supply the wafer to the cooler, the heater, and the squeegee unit that are linearly aligned in the plan view. Accordingly, the squeegee unit can be arranged inside the inner circumferential surface of the expanding ring effectively using a space inside the inner circumferential surface of the expanding ring, and thus an increase in the size of the expanding device can be further reduced or prevented. Furthermore, the wafer is supplied using the movement mechanism such that a mechanism that conveys the wafer to the squeegee unit, the cooler, and the heater can be achieved by using one linear movement mechanism, and thus the structure of the movement mechanism that supplies the wafer between a plurality of devices such as the expander and the squeegee unit can be simplified. Consequently, an increase in the size of the expanding device can be reduced or prevented, and the structure of the movement mechanism that supplies the wafer between a plurality of devices such as the expander and the squeegee unit can be simplified.

In this case, the expander and the squeegee unit inside the inner circumferential surface of the expanding ring are preferably below the heater, the squeegee unit is preferably in a straight line with the cooler in the direction in which the cooler and the heater are aligned in the plan view, and the movement mechanism is preferably operable to supply the wafer to the cooler, the expander, and the squeegee unit inside the inner circumferential surface of the expanding ring that are linearly aligned in the plan view. Accordingly, the squeegee unit arranged inside the inner circumferential surface of the expanding ring is arranged below the heater such that an increase in the size of the expanding device in the horizontal direction can be reduced or prevented as compared with a case in which the squeegee unit arranged inside the inner circumferential surface of the expanding ring is deviated from the heater in the horizontal direction. Consequently, the structure of the movement mechanism that supplies the wafer between a plurality of devices such as the expander and the squeegee unit can be simplified, and an increase in the size of the expanding device can be further reduced or prevented.

The expanding device according to the first aspect preferably further includes, in addition to the cooler and the heater, an ultraviolet irradiator to irradiate a portion of the sheet member expanded by the expander that corresponds to a position of the wafer with ultraviolet rays. The cooler and the heater are preferably linearly aligned in the plan view, the squeegee unit and the ultraviolet irradiator are preferably in a straight line with the cooler and the heater in a direction in which the cooler and the heater are aligned in the plan view, and the movement mechanism is preferably operable to supply the wafer to the cooler, the heater, the squeegee unit, and the ultraviolet irradiator that are linearly aligned in the plan view. Accordingly, the wafer is supplied using the movement mechanism such that a mechanism that conveys the wafer to the cooler, the heater, the squeegee unit, and the ultraviolet irradiator can be achieved by using one linear movement mechanism, and thus the structure of the movement mechanism that supplies the wafer between a plurality of devices such as the expander and the squeegee unit can be simplified.

In this case, the expander preferably includes an expanding ring to expand the sheet member to divide the wafer along the dividing line, the squeegee unit and the ultraviolet irradiator are preferably inside an inner circumferential surface of the expanding ring, the squeegee unit and the ultraviolet irradiator are preferably in a straight line with the cooler and the heater in the direction in which the cooler and the heater are aligned in the plan view, and the movement mechanism is preferably operable to supply the wafer to the cooler, the heater, the squeegee unit, and the ultraviolet irradiator, the cooler, the heater, the squeegee unit, and the ultraviolet irradiator being linearly aligned in the plan view, the squeegee unit and the ultraviolet irradiator being inside the inner circumferential surface of the expanding ring. Accordingly, the squeegee unit and the ultraviolet irradiator can be arranged inside the inner circumferential surface of the expanding ring effectively using the space inside the inner circumferential surface of the expanding ring, and thus an increase in the size of the expanding device can be further reduced or prevented. Furthermore, the wafer W1 is supplied using the movement mechanism such that a mechanism that conveys the wafer to the squeegee unit, the ultraviolet irradiator, the cooler, and the heater can be achieved by using one linear movement mechanism, and thus the structure of the movement mechanism that supplies the wafer between a plurality of devices such as the expander and the squeegee unit can be simplified, and an increase in the size of the expanding device can be further reduced or prevented.

The expanding device according to the first aspect preferably further includes, in addition to the cooler, a clamp unit including a gripper to hold a ring-shaped member that is attached to the sheet member while surrounding the wafer, and a linear movement mechanism as the movement mechanism to move the gripper holding the ring-shaped member. In the plan view, a center of a cooling work area in which the sheet member is cooled by the cooler and a center of a pressing work area in which the squeegee unit presses the wafer via the sheet member are preferably on a movement path of a center point of the wafer held by the gripper when the gripper is moved by the linear movement mechanism, and the linear movement mechanism is preferably operable to supply the wafer to the cooler, the expander, and the squeegee unit that are linearly aligned in the plan view. Accordingly, when the sheet member is cooled by the cooler, and when the wafer is pressed by the squeegee unit, the center point of the cooling work area and the center point of the pressing work area are not deviated in position in a direction perpendicular to the horizontal direction in which the linear movement mechanism extends with respect to the wafer held by the gripper, and thus even without a separate linear movement mechanism extending in the direction perpendicular to the horizontal direction in which the linear movement mechanism extends, both the cooling work by the cooler and the pressing work by the squeegee unit can be performed. Consequently, an increase in the number of movement mechanisms required in the expanding device can be reduced or prevented, and thus an increase in the size of the expanding device can be further reduced or prevented.

A semiconductor chip manufacturing method according to a second aspect of the present disclosure includes forming a modified layer in a wafer including a plurality of semiconductor chips by emitting a laser beam to the wafer from a laser irradiator operable to emit the laser beam, supplying the wafer to an expander operable to expand an elastic sheet member by a movement mechanism operable to supply the wafer to the expander, at least one of a cooler operable to cool the sheet member or a heater operable to heat and shrink the sheet member while maintaining a gap between the plurality of semiconductor chips, and a squeegee unit operable to locally press the wafer, the expander, at least one of the cooler or the heater, and the squeegee unit being linearly aligned in a plan view, and expanding the sheet member to divide the wafer into the plurality of semiconductor chips along a dividing line by the expander.

As described above, the semiconductor chip manufacturing method according to the second aspect of the present disclosure includes supplying the wafer to the expander operable to expand the elastic sheet member by the movement mechanism operable to supply the wafer to the expander, at least one of the cooler operable to cool the sheet member or the heater operable to heat and shrink the sheet member while maintaining the gap between the plurality of semiconductor chips, and the squeegee unit operable to locally press the wafer. The expander, at least one of the cooler or the heater, and the squeegee unit are linearly aligned in the plan view. Accordingly, the wafer is supplied to the squeegee unit, the expander, and at least one of the cooler or the heater that are linearly aligned, using the movement mechanism such that a mechanism that conveys the wafer to the squeegee unit, the expander, and at least one of the cooler or the heater can be achieved by using one linear movement mechanism, and thus the semiconductor chip manufacturing method that enables a simple structure of a movement mechanism that supplies the wafer between a plurality of devices such as the expander and the squeegee unit can be obtained.

A semiconductor chip according to a third aspect of the present disclosure is manufactured by an expanding device including an expander to expand an elastic sheet member to divide a wafer into a plurality of semiconductor chips along a dividing line, at least one of a cooler to cool the sheet member before the sheet member is expanded by the expander or a heater to heat and shrink the sheet member expanded by the expander while maintaining a gap between the plurality of semiconductor chips, a squeegee unit to locally press the wafer after the expander expands the sheet member to divide the wafer into the plurality of semiconductor chips, and a movement mechanism to supply the wafer to the expander, at least one of the cooler or the heater, and the squeegee unit, the expander, at least one of the cooler or the heater, and the squeegee unit are linearly aligned in a plan view.

Regarding the semiconductor chip according to the third aspect of the present disclosure, as described above, the expanding device includes the movement mechanism to supply the wafer to the expander, at least one of the cooler or the heater, and the squeegee unit. The expander, at least one of the cooler or the heater, and the squeegee unit are linearly aligned in the plan view. Accordingly, the wafer is supplied to the squeegee unit, the expander, and at least one of the cooler or the heater that are linearly aligned, using the movement mechanism such that a mechanism that conveys the wafer to the squeegee unit, the expander, and at least one of the cooler or the heater can be achieved by using one linear movement mechanism, and thus the semiconductor chip can be obtained by the expanding device that enables a simple structure of a movement mechanism that supplies the wafer between a plurality of devices such as the expander and the squeegee unit.

According to the present disclosure, as described above, it is possible to simplify the structure of the movement mechanism that supplies the wafer between a plurality of devices such as the expander and the squeegee.

### BRIEF DESCRIPTION OF THE DRAWINGS

FIG. 1 is a plan view showing a semiconductor wafer processing apparatus including a dicing device and an expanding device according to a first embodiment;

FIG. 2 is a plan view showing a wafer ring structure to be processed in the semiconductor wafer processing apparatus according to the first embodiment;

FIG. 3 is a sectional view taken along the line III-III in FIG. 2;

FIG. 4 is a plan view of the dicing device arranged adjacent to the expanding device according to the first embodiment;

FIG. 5 is a side view showing the dicing device arranged adjacent to the expanding device according to the first embodiment, as viewed from the Y2 direction side;

FIG. 6 is a plan view of the expanding device according to the first embodiment;

FIG. 7 is a side view showing the expanding device according to the first embodiment, as viewed from the Y2 direction side;

FIG. 8 is a side view showing the expanding device according to the first embodiment, as viewed from the X1 direction side;

FIG. 9 is a block diagram showing the control configuration of the semiconductor wafer processing apparatus according to the first embodiment;

FIG. 10 is a flowchart of the first half of a semiconductor chip manufacturing process of the semiconductor wafer processing apparatus according to the first embodiment;

FIG. 11 is a flowchart of the second half of the semiconductor chip manufacturing process of the semiconductor wafer processing apparatus according to the first embodiment;

FIG. 12 is a side view showing a state in which a sheet member is being cooled by a cold air supplier and a cooling unit of the expanding device according to the first embodiment;

FIG. 13 is a side view showing a state in which a wafer is moved to an expander by a clamp unit of the expanding device according to the first embodiment;

FIG. 14 is a side view showing a state in which the sheet member is expanded by the expander of the expanding device according to the first embodiment;

FIG. 15 is a plan view showing a relationship between a movement path of the center point of the wafer, the center point of the cooling unit, the center point of the cold air supplier, the center point of a heat shrinker, the center point of an expansion maintaining member, the center point of an ultraviolet irradiator, the center point of a squeegee, and the center point of the expander in the expanding device according to the first embodiment;

FIG. 16 is a plan view showing a semiconductor wafer processing apparatus including a dicing device and an expanding device according to a second embodiment;

FIG. 17 is a side view showing the semiconductor wafer processing apparatus including the dicing device and the expanding device according to the second embodiment, as viewed from the Y2 direction side;

FIG. 18 is a side view showing the semiconductor wafer processing apparatus including the dicing device and the expanding device according to the second embodiment, as viewed from the X1 direction side;

FIG. 19 is a block diagram showing the control configuration of the semiconductor wafer processing apparatus according to the second embodiment;

FIG. 20 is a flowchart of the first half of a semiconductor chip manufacturing process of the semiconductor wafer processing apparatus according to the second embodiment;

FIG. 21 is a flowchart of the second half of the semiconductor chip manufacturing process of the semiconductor wafer processing apparatus according to the second embodiment;

FIG. 22 is a side view showing a state in which a sheet member is being cooled by a cool air supplier and a cooling unit of the expanding device according to the second embodiment;

FIG. 23 is a side view showing a state in which the sheet member is expanded by an expander of the expanding device according to the second embodiment;

FIG. 24 is a side view showing a state in which a wafer is locally pressed by a squeegee unit of the expanding device according to the second embodiment; and

FIG. 25 is a plan view showing a relationship between a movement path of the center point of the wafer, the center point of the cooling unit, the center point of the cool air supplier, the center point of a heat shrinker, the center point of an expansion maintaining member, the center point of an ultraviolet irradiator, the center point of the squeegee, and the center point of the expander in the expanding device according to the second embodiment.

### DETAILED DESCRIPTION

Embodiments embodying the present disclosure are hereinafter described on the basis of the drawings.

### First Embodiment

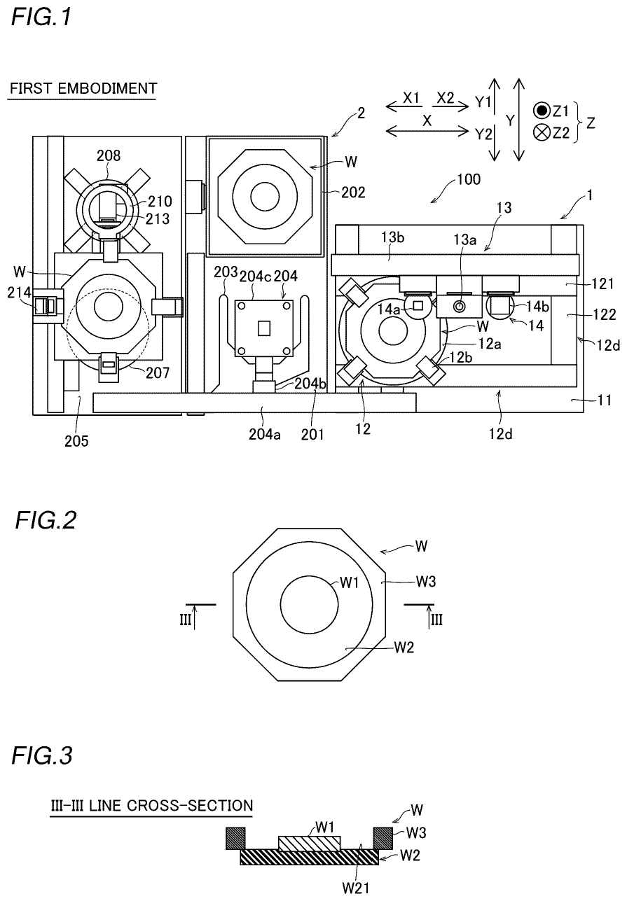

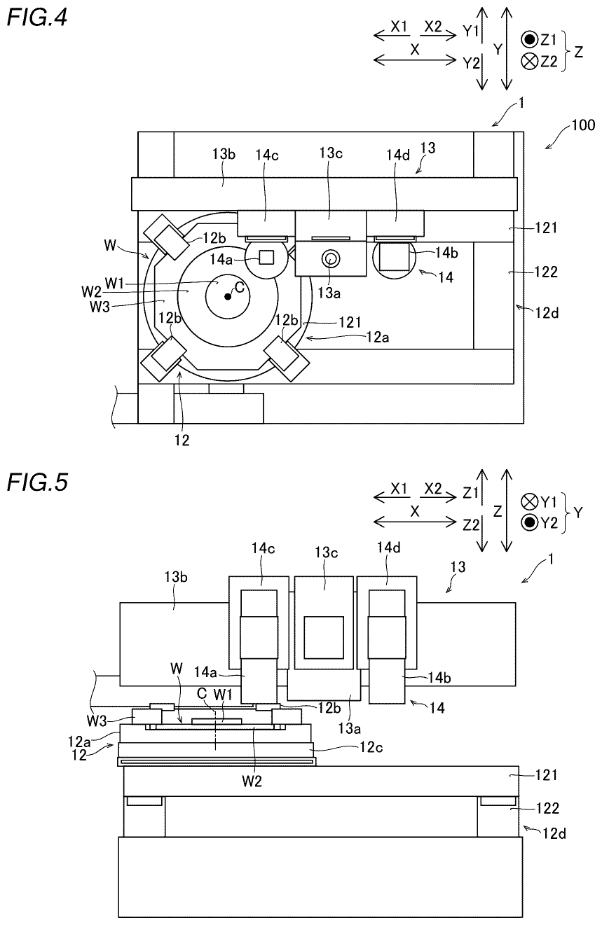

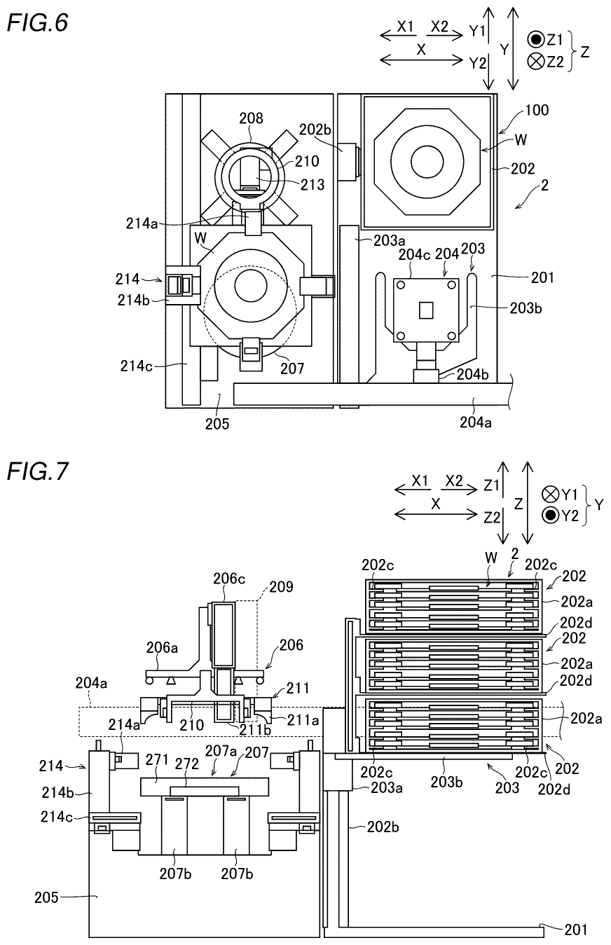

The configuration of a semiconductor wafer processing apparatus 100 according to a first embodiment of the present disclosure is now described with reference to FIGS. 1 to 15.

### Semiconductor Wafer Processing Apparatus

As shown in FIG. 1, the semiconductor wafer processing apparatus 100 is an apparatus that processes a wafer W1 provided on a wafer ring structure W. The semiconductor wafer processing apparatus 100 forms a modified layer in the wafer W1 and divides the wafer W1 along the modified layer to form a plurality of semiconductor chips Ch.

The wafer ring structure W is now described with reference to FIGS. 2 and 3. The wafer ring structure W includes the wafer W1, a sheet member W2, and a ring-shaped member W3.

The wafer W1 is a circular thin plate made of a crystal of a semiconductor material that is used as a material for a semiconductor integrated circuit. Inside the wafer W1, the modified layer is formed by modifying the inside along a dividing line by processing in the semiconductor wafer processing apparatus 100. That is, the wafer W1 is processed so as to be divisible along the dividing line. The sheet member W2 is an elastic adhesive tape. An adhesive layer is provided on the upper surface W21 of the sheet member W2. The wafer W1 is attached to the adhesive layer on the sheet member W2. The ring-shaped member W3 is a ring-shaped metal frame in a plan view. The ring-shaped member W3 is attached to the adhesive layer on the sheet member W2 while surrounding the wafer W1.

The semiconductor wafer processing apparatus 100 includes a dicing device 1 and an expanding device 2. Hereinafter, an upward-downward direction is defined as a Z direction, an upward direction is defined as a Z1 direction, and a downward direction is defined as a Z2 direction. In a horizontal direction perpendicular to the Z direction, a direction in which the dicing device 1 and the expanding device 2 are aligned is defined as an X direction, a direction from the dicing device 1 toward the expanding device 2 in the X direction is defined as an X1 direction, and a direction from the expanding device 2 toward the dicing device 1 in the X direction is defined as an X2 direction. A direction perpendicular to the X direction in the horizontal direction is defined as a Y direction, one direction in the Y direction is defined as a Y1 direction, and the other direction in the Y direction is defined as a Y2 direction.

### Dicing Device

As shown in FIGS. 1, 4, and 5, the dicing device 1 emits a laser beam having a wavelength transmissive to the wafer W1 along the dividing line (street Ws) to form the modified layer. The modified layer refers to a crack, a void, or the like formed inside the wafer W1 by the laser beam. A method for forming the modified layer in the wafer W1 in this manner is called dicing.

Specifically, the dicing device 1 includes a base 11, a chuck table unit 12, a laser 13, and an imager 14.

The base 11 is a base on which the chuck table unit 12 is installed. The base 11 has a rectangular shape in the plan view.

### Chuck Table Unit

The chuck table unit 12 includes a suction unit 12a, clamps 12b, a rotation mechanism 12c, and a table movement mechanism 12d. The suction unit 12a suctions the wafer ring structure W on the upper surface of the suction unit 12a on the Z1 direction side. The suction unit 12a is a table including a suction hole, a suction pipe line, etc. to suction the lower surface of the ring-shaped member W3 of the wafer ring structure W on the Z2 direction side. The suction unit 12a is supported by the table movement mechanism 12d via the rotation mechanism 12c. The clamps 12b are provided at an upper end of the suction unit 12a. The clamps 12b hold the wafer ring structure W suctioned by the suction unit 12a. The clamps 12b hold the ring-shaped member W3 of the wafer ring structure W suctioned by the suction unit 12a from the Z1 direction side. In this manner, the wafer ring structure W is held by the suction unit 12a and the clamps 12b.

The rotation mechanism 12c rotates the suction unit 12a in a circumferential direction around a rotation center axis C extending parallel to the Z direction. The rotation mechanism 12c is attached to an upper end of the table movement mechanism 12d. The table movement mechanism 12d moves the wafer ring structure W in the X and Y directions. The table movement mechanism 12d includes an X-direction movement mechanism 121 and a Y-direction movement mechanism 122. The X-direction movement mechanism 121 moves the rotation mechanism 12c in the X1 direction or the X2 direction. The X-direction movement mechanism 121 includes a linear conveyor module, or a ball screw and a drive including a motor with an encoder, for example. The Y-direction movement mechanism 122 moves the rotation mechanism 12c in the Y1 direction or the Y2 direction. The Y-direction movement mechanism 122 includes a linear conveyor module, or a ball screw and a drive including a motor with an encoder, for example.

### Laser

The laser 13 emits a laser beam to the wafer W1 of the wafer ring structure W held by the chuck table unit 12. The laser 13 is arranged on the Z1 direction side of the chuck table unit 12. The laser 13 includes a laser irradiator 13a, a mounting member 13b, and a Z-direction movement mechanism 13c. The laser irradiator 13a emits a pulsed laser beam. The mounting member 13b is a frame to which the laser 13 and the imager 14 are mounted. The Z-direction movement mechanism 13c moves the laser 13 in the Z1 direction or the Z2 direction. The Z-direction movement mechanism 13c includes a linear conveyor module, or a ball screw and a drive including a motor with an encoder, for example. The laser irradiator 13a may be a laser irradiator that oscillates a continuous wave laser beam other than a pulsed laser beam as a laser beam as long as a modified layer can be formed by multiphoton absorption.

### Imager

The imager 14 images the wafer W1 of the wafer ring structure W held by the chuck table unit 12. The imager 14 is arranged on the Z1 direction side of the chuck table unit 12. The imager 14 includes a high-resolution camera 14a, a wide-angle camera 14b, a Z-direction movement mechanism 14c, and a Z-direction movement mechanism 14d.

The high-resolution camera 14a and the wide-angle camera 14b are near-infrared imaging cameras. The high-resolution camera 14a has a narrower viewing angle than the wide-angle camera 14b. The high-resolution camera 14a has a higher resolution than the wide-angle camera 14b. The wide-angle camera 14b has a wider viewing angle than the high-resolution camera 14a. The wide-angle camera 14b has a lower resolution than the high-resolution camera 14a. The high-resolution camera 14a is arranged on the X1 direction side of the laser irradiator 13a. The wide-angle camera 14b is arranged on the X2 direction side of the laser irradiator 13a. Thus, the high-resolution camera 14a, the laser irradiator 13a, and the wide-angle camera 14b are arranged adjacent to each other in this order from the X1 direction side toward the X2 direction side.

The Z-direction movement mechanism 14c moves the high-resolution camera 14a in the Z1 direction or the Z2 direction. The Z-direction movement mechanism 14c includes a linear conveyor module, or a ball screw and a drive including a motor with an encoder, for example. The Z-direction movement mechanism 14d moves the wide-angle camera 14b in the Z1 direction or the Z2 direction. The Z-direction movement mechanism 14d includes a linear conveyor module, or a ball screw and a drive including a motor with an encoder, for example.

### Expanding Device

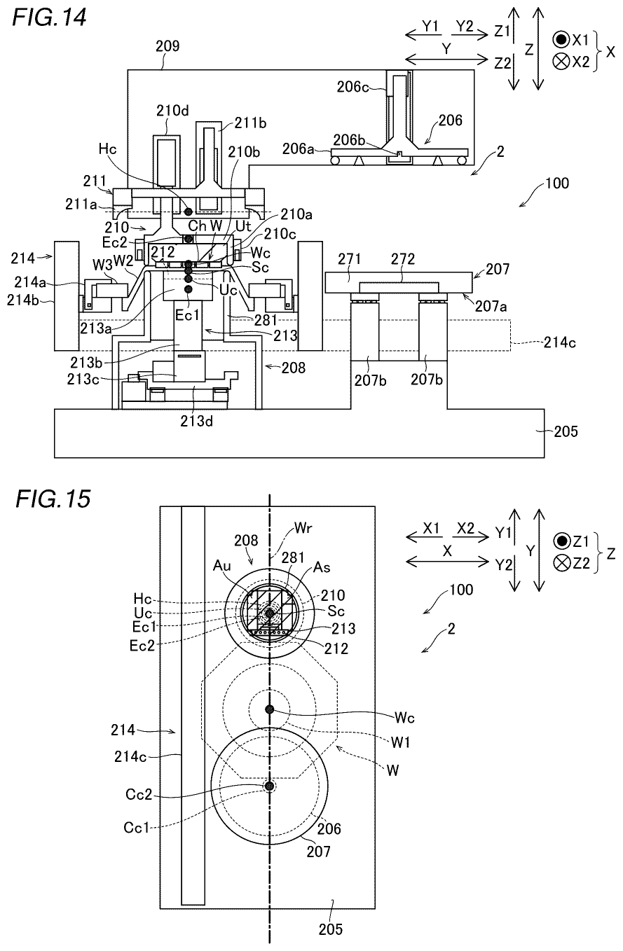

As shown in FIGS. 1, 6, and 7, the expanding device 2 divides the wafer W1 to form the plurality of semiconductor chips Ch (see FIG. 14). The expanding device 2 forms a sufficient gap between the plurality of semiconductor chips Ch. A modified layer is formed in the wafer W1 by emitting a laser beam having a wavelength transmissive to the wafer W1 along the dividing line (street Ws) in the dicing device 1. In the expanding device 2, the plurality of semiconductor chips Ch are formed by dividing the wafer W1 along the modified layer formed in advance in the dicing device 1.

Therefore, in the expanding device 2, the wafer W1 is divided along the modified layer by expanding the sheet member W2. Furthermore, in the expanding device 2, the gap between the plurality of semiconductor chips Ch formed by division is widened by expanding the sheet member W2.

The expanding device 2 includes a base 201, a cassette unit 202, a lift-up hand unit 203, a suction hand unit 204, a base 205, a cool air supplier 206, a cooling unit 207, an expander 208, a base 209, an expansion maintaining member 210, a heat shrinker 211, an ultraviolet irradiator 212, a squeegee unit 213, and a clamp unit 214. The cool air supplier 206 and the cooling unit 207 are examples of a “cooler” in the claims. The heat shrinker 211 is an example of a “heater” in the claims.

### Base

The base 201 is a base on which the cassette unit 202 and the lift-up hand unit 203 are installed. The base 201 has a rectangular shape in the plan view.

### Cassette Unit

The cassette unit 202 can accommodate a plurality of wafer ring structures W. The cassette unit 202 includes wafer cassettes 202a, a Z-direction movement mechanism 202b, and pairs of placement portions 202c.

A plurality of (three) wafer cassettes 202a are arranged in the Z direction. Each of the wafer cassettes 202a has an accommodation space capable of accommodating a plurality of (five) wafer ring structures W. The wafer ring structure W is manually supplied and placed in the wafer cassette 202a. The wafer cassette 202a may accommodate one to four wafer ring structures W, or may accommodate six or more wafer ring structures W. Furthermore, one, two, or four or more wafer cassettes 202a may be arranged in the Z direction.

The Z-direction movement mechanism 202b moves the wafer cassettes 202a in the Z1 direction or the Z2 direction. The Z-direction movement mechanism 202b includes a linear conveyor module, or a ball screw and a drive including a motor with an encoder, for example. The Z-direction movement mechanism 202b also includes mounting tables 202d that support the wafer cassettes 202a from below. A plurality of (three) mounting tables 202d are arranged according to the positions of the plurality of wafer cassettes 202a.

A plurality of (five) pairs of placement portions 202c are arranged inside the wafer cassette 202a. The ring-shaped member W3 of the wafer ring structure W is placed on the pair of placement portions 202c from the Z1 direction side. One of the pair of placement portions 202c protrudes in the X2 direction from the inner surface of the wafer cassette 202a on the X1 direction side. The other of the pair of placement portions 202c protrudes in the X1 direction from the inner surface of the wafer cassette 202a on the X2 direction side.

### Lift-Up Hand Unit

The lift-up hand unit 203 can take out the wafer ring structure W from the cassette unit 202. Furthermore, the lift-up hand unit 203 can take the wafer ring structure W into the cassette unit 202.

Specifically, the lift-up hand unit 203 includes a Y-direction movement mechanism 203a and a lift-up hand 203b. The Y-direction movement mechanism 203a includes a linear conveyor module, or a ball screw and a drive including a motor with an encoder, for example. The lift-up hand 203b supports the ring-shaped member W3 of the wafer ring structure W from the Z2 direction side.

### Suction Hand Unit

The suction hand unit 204 suctions the ring-shaped member W3 of the wafer ring structure W from the Z1 direction side.

Specifically, the suction hand unit 204 includes an X-direction movement mechanism 204a, a Z-direction movement mechanism 204b, and a suction hand 204c. The X-direction movement mechanism 204a moves the suction hand 204c in the X direction. The Z-direction movement mechanism 204b moves the suction hand 204c in the Z direction. Each of the X-direction movement mechanism 204a and the Z-direction movement mechanism 204b includes a linear conveyor module, or a ball screw and a drive including a motor with an encoder, for example. The suction hand 204c suctions and supports the ring-shaped member W3 of the wafer ring structure W from the Z1 direction side. The suction hand 204c supports the ring-shaped member W3 of the wafer ring structure W by generating a negative pressure.

### Base

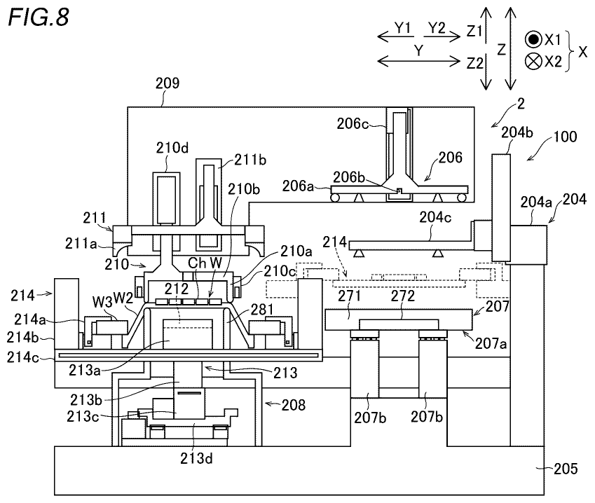

As shown in FIGS. 7 and 8, the base 205 is a base on which the expander 208, the cooling unit 207, the ultraviolet irradiator 212, and the squeegee unit 213 are installed. The base 205 has a rectangular shape in the plan view. In FIG. 8, the clamp unit 214 arranged on the Z1 direction side of the cooling unit 207 is indicated by dotted lines.

### Cool Air Supplier

The cool air supplier 206 supplies cool air to the sheet member W2 from the Z1 direction side when the sheet member W2 is expanded by the expander 208.

Specifically, the cool air supplier 206 includes a supplier main body 206a, a cool air supply port 206b, and a movement mechanism 206c. The cool air supply port 206b allows cool air supplied from a cool air supply device to flow out therethrough. The cool air supply port 206b is provided at an end of the supplier main body 206a on the Z2 direction side. The cool air supply port 206b is arranged in a central portion of the end of the supplier main body 206a on the Z2 direction side. The movement mechanism 206c includes a linear conveyor module, or a ball screw and a motor with an encoder, for example.

The cool air supply device is a device that generates cool air. The cool air supply device supplies air cooled by a heat pump, for example. Such a cool air supply device is installed on the base 205. The cool air supplier 206 and the cool air supply device are connected to each other by a hose (not shown).

### Cooling Unit

The cooling unit 207 cools the sheet member W2 from the Z2 direction side.

Specifically, the cooling unit 207 includes a cooling member 207a including a cooling body 271 and a Peltier element 272, and a Z-direction movement mechanism 207b. The cooling body 271 is made of a member having a large heat capacity and a high thermal conductivity. The cooling body 271 is made of metal such as aluminum. The Peltier element 272 cools the cooling body 271. The cooling body 271 is not limited to aluminum, and may be another member having a large heat capacity and a high thermal conductivity. The Z-direction movement mechanism 207b is a cylinder.

The cooling unit 207 is movable in the Z1 direction or the Z2 direction by the Z-direction movement mechanism 207b. Thus, the cooling unit 207 is movable to a position contacting the sheet member W2 and a position spaced apart from the sheet member W2.

### Expander

The expander 208 expands the sheet member W2 of the wafer ring structure W to divide the wafer W1 along the dividing line.

Specifically, the expander 208 includes an expanding ring 281. The expanding ring 281 expands the sheet member W2 by supporting the sheet member W2 from the Z2 direction side. The expanding ring 281 has a ring shape in the plan view.

### Base

The base 209 is a base material on which the cool air supplier 206, the expansion maintaining member 210, and the heat shrinker 211 are installed.

### Expansion Maintaining Member

As shown in FIGS. 7 and 8, the expansion maintaining member 210 holds down the sheet member W2 from the Z1 direction side such that the sheet member W2 in the vicinity of the wafer W1 does not shrink due to heating by a heating ring 211a.

Specifically, the expansion maintaining member 210 includes a pressing ring 210a, a lid 210b, and an intake 210c. The pressing ring 210a has a ring shape in the plan view. The lid 210b is provided on the pressing ring 210a to cover an opening of the pressing ring 210a. The intake 210c is an intake ring having a ring shape in the plan view. A plurality of intake ports are formed in the lower surface of the intake 210c on the Z2 direction side. The pressing ring 210a is moved in the Z direction by a Z-direction movement mechanism 210d. That is, the Z-direction movement mechanism 210d moves the pressing ring 210a to a position at which the sheet member W2 is held down and a position away from the sheet member W2. The Z-direction movement mechanism 210d includes a linear conveyor module, or a ball screw and a drive including a motor with an encoder, for example.

### Heat Shrinker

The heat shrinker 211 shrinks the sheet member W2 expanded by the expander 208 by heating while maintaining the gap between the plurality of semiconductor chips Ch.

The heat shrinker 211 includes the heating ring 211a and a Z-direction movement mechanism 211b. The heating ring 211a has a ring shape in the plan view. The heating ring 211a includes a sheathed heater that heats the sheet member W2. The Z-direction movement mechanism 211b moves the heating ring 211a in the Z direction. The Z-direction movement mechanism 211b includes a linear conveyor module, or a ball screw and a drive including a motor with an encoder, for example.

### Ultraviolet Irradiator

The ultraviolet irradiator 212 emits ultraviolet rays Ut to the sheet member W2 in order to reduce the adhesive strength of the adhesive layer of the sheet member W2. Specifically, the ultraviolet irradiator 212 includes an ultraviolet illuminator. The ultraviolet irradiator 212 is arranged at an end of a press 213a of the squeegee unit 213, which is described below, on the Z1 direction side. The ultraviolet irradiator 212 emits the ultraviolet rays Ut to the sheet member W2 while moving together with the squeegee unit 213.

### Squeegee Unit

The squeegee unit 213 further divides the wafer W1 along the modified layer by locally pressing the wafer W1 from the Z2 direction side after the sheet member W2 is expanded. Specifically, the squeegee unit 213 includes the press 213a, a Z-direction movement mechanism 213b, an X-direction movement mechanism 213c, and a rotation mechanism 213d.

The press 213a generates a bending stress in the wafer W1 to divide the wafer W1 along the modified layer by being moved by the rotation mechanism 213d and the X-direction movement mechanism 213c while pressing the wafer W1 from the Z2 direction side via the sheet member W2. The press 213a presses the wafer W1 via the sheet member W2 by being raised to a raised position on the Z1 direction side by the Z-direction movement mechanism 213b. When the press 213a is lowered to a lowered position on the Z2 direction side by the Z-direction movement mechanism 213b, the wafer W1 is no longer pressed. The press 213a is a squeegee.

The press 213a is attached to an end of the Z-direction movement mechanism 213b on the Z1 direction side. The Z-direction movement mechanism 213b linearly moves the press 213a in the Z1 direction or the Z2 direction. The Z-direction movement mechanism 213b is a cylinder, for example. The Z-direction movement mechanism 213b is attached to an end of the X-direction movement mechanism 213c on the Z1 direction side.

The X-direction movement mechanism 213c is attached to an end of the rotation mechanism 213d on the Z1 direction side. The X-direction movement mechanism 213c linearly moves the press 213a in one direction. The X-direction movement mechanism 213c includes a linear conveyor module, or a ball screw and a drive including a motor with an encoder, for example.

In the squeegee unit 213, the press 213a is raised to the raised position by the Z-direction movement mechanism 213b. In the squeegee unit 213, the press 213a is moved in the Y direction by the X-direction movement mechanism 213c while locally pressing the wafer W1 from the Z2 direction side via the sheet member W2 such that the wafer W1 is divided. In the squeegee unit 213, the press 213a is lowered to the lowered position by the Z-direction movement mechanism 213b. In the squeegee unit 213, after the press 213a finishes moving in the Y direction, the press 213a is rotated 90 degrees by the rotation mechanism 213d.

In the squeegee unit 213, the press 213a is raised to the raised position by the Z-direction movement mechanism 213b. In the squeegee unit 213, after the press 213a is rotated 90 degrees, the press 213a is moved in the X direction by the X-direction movement mechanism 213c while locally pressing the wafer W1 from the Z2 direction side via the sheet member W2 such that the wafer W1 is divided.

### Clamp Unit

The clamp unit 214 holds the ring-shaped member W3 of the wafer ring structure W. Specifically, the clamp unit 214 includes a gripper 214a, a Z-direction movement mechanism 214b, and a Y-direction movement mechanism 214c. The gripper 214a supports the ring-shaped member W3 from the Z2 direction side and holds down the ring-shaped member W3 from the Z1 direction side. Thus, the ring-shaped member W3 is held by the gripper 214a. The gripper 214a is attached to the Z-direction movement mechanism 214b. The Y-direction movement mechanism 214c is an example of a “linear movement mechanism” in the claims.

The Z-direction movement mechanism 214b moves the clamp unit 214 in the Z direction. Specifically, the Z-direction movement mechanism 214b moves the gripper 214a in the Z1 direction or the Z2 direction. The Z-direction movement mechanism 214b includes a linear conveyor module, or a ball screw and a drive including a motor with an encoder, for example. The Z-direction movement mechanism 214b is attached to the Y-direction movement mechanism 214c. The Y-direction movement mechanism 214c moves the Z-direction movement mechanism 214b in the Y1 direction or the Y2 direction. The Y-direction movement mechanism 214c includes a linear conveyor module, or a ball screw and a drive including a motor with an encoder, for example.

### Control Configuration of Semiconductor Wafer Processing Apparatus

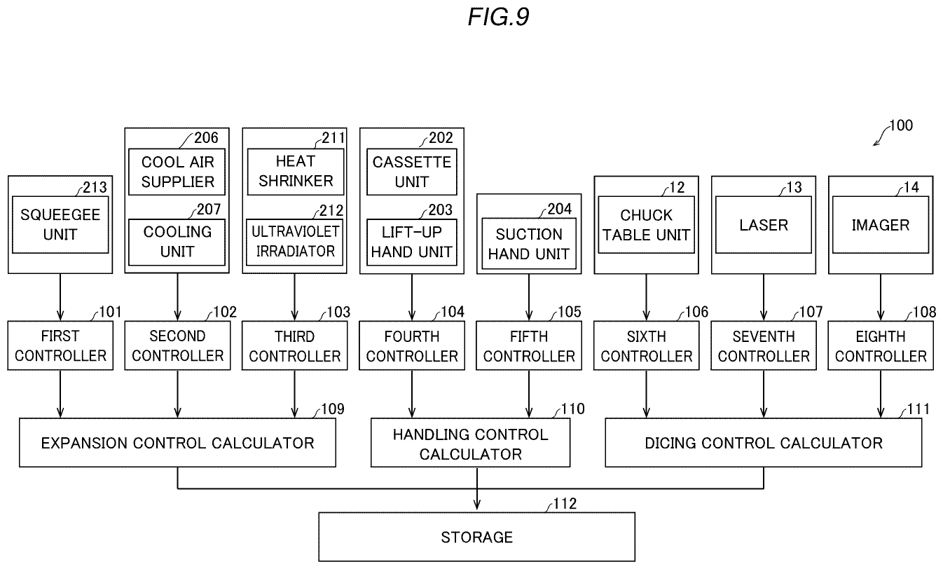

As shown in FIG. 9, the semiconductor wafer processing apparatus 100 includes a first controller 101, a second controller 102, a third controller 103, a fourth controller 104, a fifth controller 105, a sixth controller 106, a seventh controller 107, an eighth controller 108, an expansion control calculator 109, a handling control calculator 110, a dicing control calculator 111, and a storage 112.

The first controller 101 controls the squeegee unit 213. The first controller 101 includes a central processing unit (CPU) and a storage including a read-only memory (ROM) and a random access memory (RAM), for example. The first controller 101 may include, as a storage, a hard disk drive (HDD) that retains stored information even after the voltage is cut off, for example. The HDD may be provided in common for the first controller 101, the second controller 102, the third controller 103, the fourth controller 104, the fifth controller 105, the sixth controller 106, the seventh controller 107, and the eighth controller 108.

The second controller 102 controls the cool air supplier 206 and the cooling unit 207. The second controller 102 includes a CPU and a storage including a ROM and a RAM, for example. The third controller 103 controls the heat shrinker 211 and the ultraviolet irradiator 212. The third controller 103 includes a CPU and a storage including a ROM and a RAM, for example. The second controller 102 and the third controller 103 may include, as a storage, an HDD that retains stored information even after the voltage is cut off.

The fourth controller 104 controls the cassette unit 202 and the lift-up hand unit 203. The fourth controller 104 includes a CPU and a storage including a ROM and a RAM, for example. The fifth controller 105 controls the suction hand unit 204. The fifth controller 105 includes a CPU and a storage including a ROM and a RAM, for example. The fourth controller 104 and the fifth controller 105 may include, as a storage, an HDD that retains stored information even after the voltage is cut off, for example.

The sixth controller 106 controls the chuck table unit 12. The sixth controller 106 includes a CPU and a storage including a ROM and a RAM, for example. The seventh controller 107 controls the laser 13. The seventh controller 107 includes a CPU and a storage including a ROM and a RAM, for example. The eighth controller 108 controls the imager 14. The eighth controller 108 includes a CPU and a storage including a ROM and a RAM, for example. The sixth controller 106, the seventh controller 107, and the eighth controller 108 may include, as a storage, an HDD that retains stored information even after the voltage is cut off, for example.

The expansion control calculator 109 performs calculations regarding a process to expand the sheet member W2 based on the processing results of the first controller 101, the second controller 102, and the third controller 103. The expansion control calculator 109 includes a CPU and a storage including a ROM and a RAM, for example.

The handling control calculator 110 performs calculations regarding a process to move the wafer ring structure W based on the processing results of the fourth controller 104 and the fifth controller 105. The handling control calculator 110 includes a CPU and a storage including a ROM and a RAM, for example.

The dicing control calculator 111 performs calculations regarding a process to dice the wafer W1 based on the processing results of the sixth controller 106, the seventh controller 107, and the eighth controller 108. The dicing control calculator 111 includes a CPU and a storage including a ROM and a RAM, for example.

The storage 112 stores programs for operating the dicing device 1 and the expanding device 2. The storage 112 includes a ROM, a RAM, and an HDD, for example.

### Semiconductor Chip Manufacturing Process

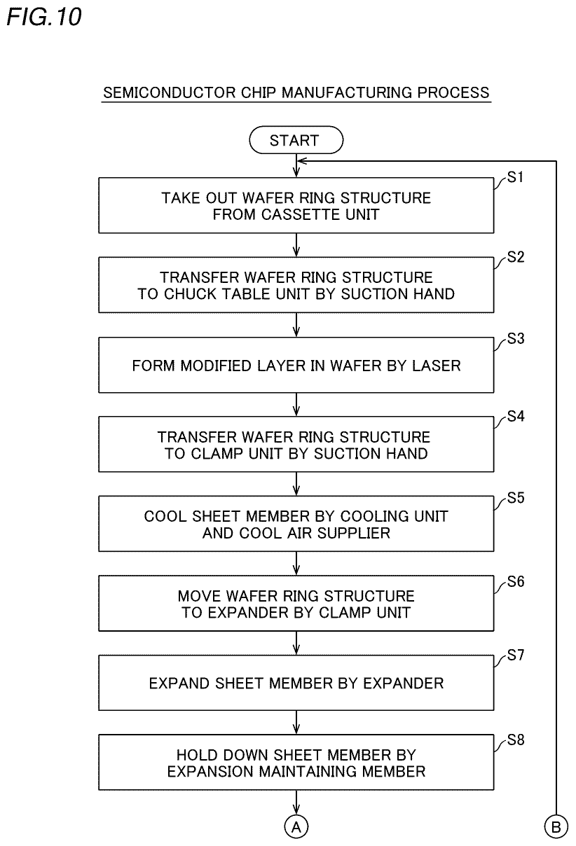

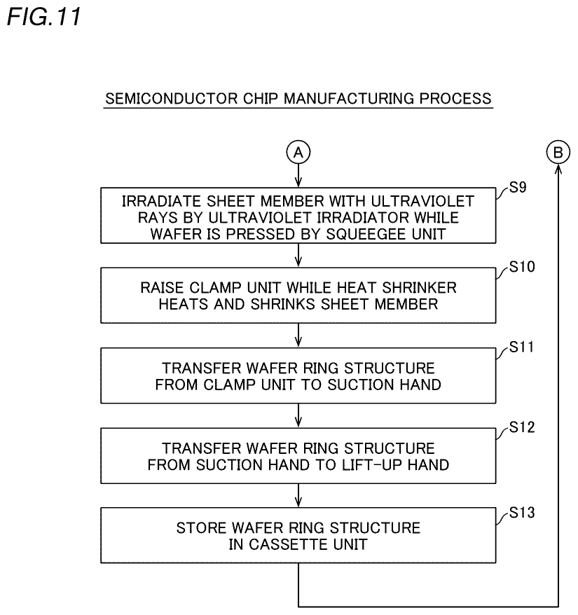

The overall operation of the semiconductor wafer processing apparatus 100 is described below with reference to FIGS. 10 and 11.

In step S1, the wafer ring structure W is taken out from the cassette unit 202. That is, after the wafer ring structure W stored in the cassette unit 202 is supported by the lift-up hand 203b, the lift-up hand 203b is moved in the Y1 direction by the Y-direction movement mechanism 203a such that the wafer ring structure W is taken out from the cassette unit 202. In step S2, the wafer ring structure W is transferred to the chuck table unit 12 of the dicing device 1 by the suction hand 204c. That is, the wafer ring structure W taken out from the cassette unit 202 is moved in the X2 direction by the X-direction movement mechanism 204a while being suctioned by the suction hand 204c. The wafer ring structure W that has been moved in the X2 direction is transferred from the suction hand 204c to the chuck table unit 12 and then held by the chuck table unit 12.

In step S3, a modified layer is formed in the wafer W1 by the laser 13. In step S4, the wafer ring structure W including the wafer W1 in which the modified layer has been formed is transferred to the clamp unit 214 by the suction hand 204c. In step S5, the sheet member W2 is cooled by the cool air supplier 206 and the cooling unit 207. That is, the wafer ring structure W held by the clamp unit 214 is moved (lowered) in the Z2 direction by the Z-direction movement mechanism 214b to contact the cooling unit 207, and the cool air supplier 206 supplies cool air from the Z1 direction side to cool the sheet member W2.

In step S6, the wafer ring structure W is moved to the expander 208 by the clamp unit 214. That is, the wafer ring structure W with the cooled sheet member W2 is moved in the Y1 direction by the Y-direction movement mechanism 214c while being held by the clamp unit 214. In step S7, the sheet member W2 is expanded by the expander 208. That is, the wafer ring structure W is moved in the Z2 direction by the Z-direction movement mechanism 214b while being held by the clamp unit 214. Then, the sheet member W2 contacts the expanding ring 281 and is expanded by being pulled by the expanding ring 281. Thus, the wafer W1 is divided along the dividing line (modified layer).

In step S8, the expanded sheet member W2 is held down from the Z1 direction side by the expansion maintaining member 210. That is, the pressing ring 210a is moved (lowered) in the Z2 direction by the Z-direction movement mechanism 210d until it contacts the sheet member W2. Then, the process advances from a point A in FIG. 10 through a point A in FIG. 11 to step S9.

As shown in FIG. 11, in step S9, after the sheet member W2 is held down by the expansion maintaining member 210, the sheet member W2 is irradiated with ultraviolet rays Ut by the ultraviolet irradiator 212 while the wafer W1 is pressed by the squeegee unit 213. Thus, the wafer W1 is further divided by the squeegee unit 213. In addition, the adhesive strength of the sheet member W2 is reduced by the ultraviolet rays Ut emitted from the ultraviolet irradiator 212.

In step S10, while the heat shrinker 211 heats and shrinks the sheet member W2, the clamp unit 214 is raised. At this time, the intake 210c takes in air in the vicinity of the heated sheet member W2. In step S11, the wafer ring structure W is transferred from the clamp unit 214 to the suction hand 204c. That is, the wafer ring structure W is moved in the Y2 direction by the Y-direction movement mechanism 214c while being held by the clamp unit 214. Then, the wafer ring structure W is suctioned by the suction hand 204c after the holding by the clamp unit 214 is released on the Z1 direction side of the cooling unit 207.

In step S12, the wafer ring structure W is transferred to the lift-up hand 203b by the suction hand 204c. In step S13, the wafer ring structure W is stored in the cassette unit 202. That is, the wafer ring structure W supported by the lift-up hand 203b is moved in the Y1 direction by the Y-direction movement mechanism 203a to be stored in the cassette unit 202. Thus, the process performed on one wafer ring structure W is terminated. Then, the process returns from a point B in FIG. 11 through a point B in FIG. 10 to step S1.

### Arrangement Positions of Cool Air Supplier, Cooling Unit, Expander, Expansion Maintaining Member, Heat Shrinker, Ultraviolet Irradiator, and Squeegee Unit

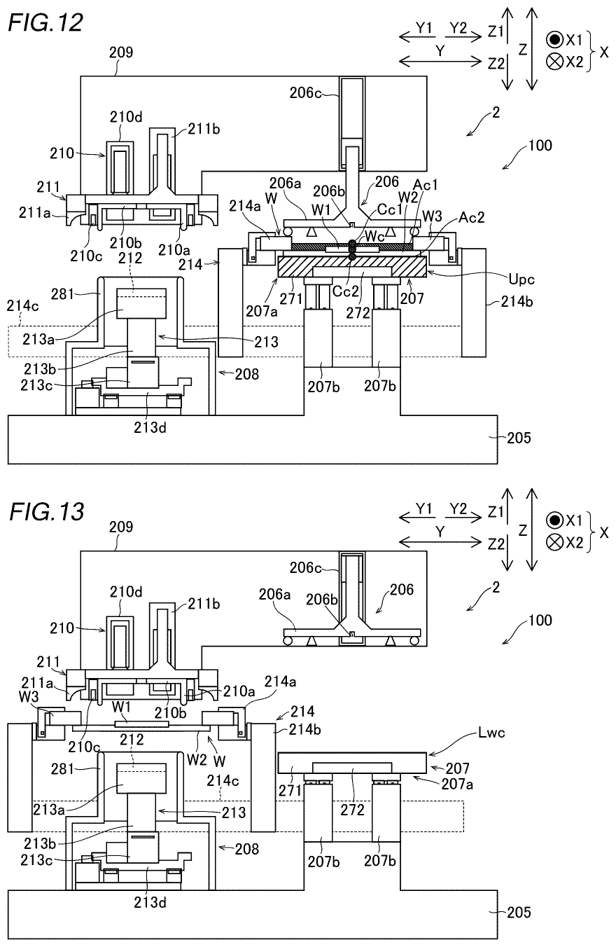

The arrangement positions of the cool air supplier 206, the cooling unit 207, the expander 208, the expansion maintaining member 210, the heat shrinker 211, the ultraviolet irradiator 212, and the squeegee unit 213 in the plan view are now described with reference to FIGS. 12 to 15.

As shown in FIG. 12, the expanding device 2 includes the cool air supplier 206, the cooling unit 207, the expander 208, the expansion maintaining member 210, the heat shrinker 211, the ultraviolet irradiator 212, the squeegee unit 213, and the clamp unit 214. In FIG. 12, the suction hand unit 204 is not shown for the convenience of illustration.

As shown in FIGS. 12 and 13, the cool air supplier 206 cools the sheet member W2 before the sheet member W2 is expanded by the expander 208. Specifically, the cool air supplier 206 includes the supplier main body 206a, the cool air supply port 206b, and the movement mechanism 206c.

In the cool air supplier 206, the supplier main body 206a is lowered to a lowered position by the movement mechanism 206c, and then the cool air is discharged through the cool air supply port 206b. At this time, the cool air discharged through the cool air supply port 206b is accumulated in a cooling work area Ac1 on the wafer W1 side (inside) of the ring-shaped member W3 of the wafer ring structure W, and thus a portion of the sheet member W2 corresponding to the cooling work area Ac1 is cooled. In the horizontal direction perpendicular to the Z direction, the center of the cooling work area Ac1 of the cool air supplier 206 is a center point Cc1.

After the cool air supplier 206 finishes cooling the portion of the sheet member W2 corresponding to the cooling work area Ac1, a cool air supply from the cool air supplier 206 is stopped, and the supplier main body 206a is raised to a raised position by the movement mechanism 206c.

The cool air supplier 206 can move up and down so as not to interfere with the expander 208, the heat shrinker 211, and the clamp unit 214. Specifically, the cool air supplier 206 can move down to a working position at which the cool air supplier 206 does not interfere with the adjacent expander 208 and heat shrinker 211, and the clamp unit 214. The cool air supplier 206 can move up to a retracted position at which the cool air supplier 206 does not interfere with the adjacent expander 208 and heat shrinker 211, and the clamp unit 214.

### Cooling Unit

The cooling unit 207 that cools the sheet member W2 before the sheet member W2 is expanded by the expander 208 includes the cooling member 207a including the cooling body 271 and the Peltier element 272, and the Z-direction movement mechanism 207b.

In the cooling unit 207, the cooling member 207a is raised to a raised position Upc by the Z-direction movement mechanism 207b, and then the cooling body 271 is cooled by the Peltier element 272 such that a portion of the sheet member W2 that contacts the cooling body 271 in the Z direction is cooled. Thus, the portion of the sheet member W2 that contacts the cooling body 271 in the Z direction is a cooling work area Ac2 of the cooling unit 207. In the horizontal direction perpendicular to the Z direction, the center of the cooling work area Ac2 of the cooling unit 207 is a center point Cc2. In the Z direction, the center points Cc1 and Cc2 overlap each other.

After the cooling unit 207 finishes cooling a portion of the sheet member W2 corresponding to the cooling work area Ac2, the cooling by the cooling unit 207 is stopped, and the cooling member 207a is lowered to a lowered position Lwc by the Z-direction movement mechanism 207b.

The cooling unit 207 can move up and down so as not to interfere with the expander 208, the heat shrinker 211, and the clamp unit 214. Specifically, the cooling unit 207 can move up to a working position (raised position Upc) at which the cooling unit 207 does not interfere with the adjacent expander 208 and heat shrinker 211, and the clamp unit 214. The cooling unit 207 can move down to a retracted position (lowered position Lwc) at which the cooling unit 207 does not interfere with the adjacent expander 208 and heat shrinker 211, and the clamp unit 214.

### Expander

As shown in FIGS. 13 and 14, the expander 208 divides the wafer W1 into the plurality of semiconductor chips Ch along the dividing line (street Ws) by expanding the elastic sheet member W2. Specifically, the expander 208 includes the expanding ring 281. The expanding ring 281 is a ring-shaped member that divides the wafer W1 along the dividing line by expanding the sheet member W2.

The expanding ring 281 is fixed to the base 205. The expander 208 does not include a movement mechanism to move the expanding ring 281 in the Z1 direction or the Z2 direction. The arrangement position of the expanding ring 281 is fixed in the Z direction and the horizontal direction. The expander 208 is arranged below the heat shrinker 211. That is, the expanding ring 281 is arranged below the heat shrinker 211. In the plan view, the center of the ring-shaped expanding ring 281 is a center point Ec1.

### Expansion Maintaining Member

The expansion maintaining member 210 includes the pressing ring 210a, the lid 210b, the intake 210c, and the Z-direction movement mechanism 210d. The pressing ring 210a is a ring-shaped member. In the plan view, the center of the ring-shaped pressing ring 210a is a center point Ec2.

In the expansion maintaining member 210, the pressing ring 210a is lowered to a lowered position by the Z-direction movement mechanism 210d such that the sheet member W2 of the wafer ring structure W is held down. In the expansion maintaining member 210, after the heat shrinker 211 finishes heating the sheet member W2, the pressing ring 210a is raised to a raised position by the Z-direction movement mechanism 210d.

The expansion maintaining member 210 can move up and down so as not to interfere with the cooling unit 207 and the clamp unit 214. Specifically, the expansion maintaining member 210 can move down to a working position at which the expansion maintaining member 210 does not interfere with the adjacent cooling unit 207 and the clamp unit 214. The expansion maintaining member 210 can move up to a retracted position at which the expansion maintaining member 210 does not interfere with the adjacent cooling unit 207 and the clamp unit 214.

### Heat Shrinker

The heat shrinker 211 heats and shrinks the sheet member W2 expanded by the expander 208 while maintaining the gap between the plurality of semiconductor chips Ch. Specifically, the heat shrinker 211 includes the heating ring 211a and the Z-direction movement mechanism 211b. The heating ring 211a has a ring shape in the plan view. In the plan view, the center of the ring-shaped heating ring 211a is a center point Hc.

In the heat shrinker 211, the heating ring 211a is lowered to a lowered position by the Z-direction movement mechanism 211b such that the sheet member W2 is heated. After the heat shrinker 211 finishes heating the sheet member W2, the heating ring 211a is raised to a raised position by the Z-direction movement mechanism 211b.

The heat shrinker 211 can move up and down so as not to interfere with the cooling unit 207 and the clamp unit 214. Specifically, the heat shrinker 211 can move down to a working position at which the heat shrinker 211 does not interfere with the adjacent cooling unit 207 and the clamp unit 214. The heat shrinker 211 can move up to a retracted position at which the heat shrinker 211 does not interfere with the adjacent cooling unit 207 and the clamp unit 214.

### Ultraviolet Irradiator

As shown in FIGS. 14 and 15, the ultraviolet irradiator 212 irradiates a portion of the sheet member W2 expanded by the expander 208 that corresponds to the position of the wafer W1 with ultraviolet rays Ut. Specifically, the ultraviolet irradiator 212 includes an ultraviolet illuminator. The ultraviolet irradiator 212 is arranged at the end of the press 213a (described below) of the squeegee unit 213 on the Z1 direction side.

The ultraviolet irradiator 212 irradiates the sheet member W2 corresponding to the position of the wafer W1 with ultraviolet rays Ut while moving together with the squeegee unit 213. Therefore, when the press 213a is moved in the Y1 direction from the Y2 direction side by the X-direction movement mechanism 213c, the ultraviolet irradiator 212 moves together with the press 213a in the Y1 direction from the Y2 direction side. When the press 213a is moved in the X1 direction from the X2 direction side by the X-direction movement mechanism 213c, the ultraviolet irradiator 212 moves together with the press 213a in the X1 direction from the X2 direction side. Thus, an ultraviolet irradiation work area Au in which ultraviolet rays are radiated by the ultraviolet irradiator 212 has an X shape in the plan view. In the plan view, the center of the ultraviolet irradiation work area Au is a center point Uc.

### Squeegee Unit

The squeegee unit 213 locally presses the wafer W1 after the expander 208 expands the sheet member W2 to divide the wafer W1 into the plurality of semiconductor chips Ch. Specifically, the squeegee unit 213 includes the press 213a, the Z-direction movement mechanism 213b, the X-direction movement mechanism 213c, and the rotation mechanism 213d.

The squeegee unit 213 is arranged inside the inner circumferential surface of the expanding ring 281. That is, the press 213a, the Z-direction movement mechanism 213b, the X-direction movement mechanism 213c, and the rotation mechanism 213d are arranged inside the inner circumferential surface of the expanding ring 281 in the plan view.

In the squeegee unit 213, when the press 213a is moved in the Y1 direction from the Y2 direction side by the X-direction movement mechanism 213c, the press 213a locally presses the sheet member W2 corresponding to the position of the wafer W1. In the squeegee unit 213, when the press 213a is moved in the X1 direction from the X2 direction side by the X-direction movement mechanism 213c, the press 213a locally presses the sheet member W2 corresponding to the position of the wafer W1. Thus, a pressing work area As in which the squeegee unit 213 locally presses the wafer W1 has a cross shape in the plan view. In the plan view, the center of the pressing work area As is a center point Sc. In the Z direction, the center point He (shown by a dotted circle in FIG. 15), the center point Ec (shown by a dotted circle in FIG. 15), the center point Ec2 (shown by a dotted circle in FIG. 15), the center point Uc (shown by a dotted circle in FIG. 15), and the center point Sc overlap each other. In FIG. 15, the sizes of points showing the center point Hc, the center point Ec1, the center point Ec2, the center point Uc, and the center point Sc are different from each other for the convenience of illustration.

### Clamp Unit

The clamp unit 214 holds the ring-shaped member W3 of the wafer ring structure W. Specifically, the clamp unit 214 includes the gripper 214a, the Z-direction movement mechanism 214b, and the Y-direction movement mechanism 214c. The Z-direction movement mechanism 214b and the Y-direction movement mechanism 214c are common conveyance mechanisms for conveying the wafer W1 to the cool air supplier 206, the cooling unit 207, the expander 208, the expansion maintaining member 210, the heat shrinker 211, the ultraviolet irradiator 212, and the squeegee unit 213.

### Linear Positional Relationship

As shown in FIG. 15, in the expanding device 2 according to the first embodiment, the expander 208, at least one of the cool air supplier 206, the cooling unit 207, or the heat shrinker 211, and the squeegee unit 213 are linearly aligned in the plan view. Thus, the Y-direction movement mechanism 214c supplies the wafer W1 to the expander 208, at least one of the cool air supplier 206, the cooling unit 207, or the heat shrinker 211, and the squeegee unit 213 that are linearly aligned in the plan view.

The cooling unit 207 is arranged below the cool air supplier 206. The expander 208 is arranged below the heat shrinker 211. The squeegee unit 213 and the ultraviolet irradiator 212 are arranged inside the inner circumferential surface of the expanding ring 281. The expander 208, and the squeegee unit 213 and the ultraviolet irradiator 212 arranged inside the inner circumferential surface of the expanding ring 281 are arranged below the heat shrinker 211.

The cool air supplier 206, the cooling unit 207, and the expander 208 arranged below the heat shrinker 211 are linearly aligned in the plan view. In addition, the squeegee unit 213 is arranged in a straight line with the cool air supplier 206, the cooling unit 207, and the expander 208 in a direction (Y direction) in which the cool air supplier 206, the cooling unit 207, and the expander 208 are aligned in the plan view.

That is, the center point Sc of the pressing work area As of the squeegee unit 213 is located on a movement path Wr of the center point We of the wafer W1 together with the center point Cc1 of the cool air supplier 206, the center point Cc2 (shown by a dotted circle in FIG. 15) of the cooling unit 207, and the center point Ec1 of the expander 208. The movement path Wr of the center point We of the wafer W1 refers to a path along which the center point We of the wafer W1 held by the gripper 214a moves when the gripper 214a is moved by the Y-direction movement mechanism 214c. The movement path Wr of the center point We of the wafer W1 extends along the Y direction.

Thus, the Y-direction movement mechanism 214c supplies the wafer W1 to the expander 208, the cool air supplier 206, the cooling unit 207, and the squeegee unit 213 that are linearly aligned in the plan view.

The cool air supplier 206, the cooling unit 207, and the heat shrinker 211 are linearly aligned in the plan view. The squeegee unit 213 is arranged in a straight line with the cool air supplier 206 and the cooling unit 207 in a direction (Y direction) in which the cool air supplier 206, the cooling unit 207, and the heat shrinker 211 are aligned in the plan view.

That is, the center point Sc of the pressing work area As of the squeegee unit 213 is located on the movement path Wr of the center point We of the wafer W1 together with the center point Cc1 of the cool air supplier 206, the center point Cc2 of the cooling unit 207, and the center point He of the heat shrinker 211.

Thus, the Y-direction movement mechanism 214c supplies the wafer W1 to the cool air supplier 206, the cooling unit 207, the heat shrinker 211, and the squeegee unit 213 that are linearly aligned in the plan view.

The squeegee unit 213 is arranged in a straight line with the cool air supplier 206 and the cooling unit 207 in the direction (Y direction) in which the cool air supplier 206, the cooling unit 207, and the heat shrinker 211 are aligned in the plan view.

That is, in the plan view, the center point Cc1 of the cooling work area Ac1 in which the sheet member W2 is cooled by the cool air supplier 206, the center point Cc2 of the cooling work area Ac2 in which the sheet member W2 is cooled by the cooling unit 207, and the center point Sc of the pressing work area As in which the squeegee unit 213 presses the wafer W1 via the sheet member W2 are located on the movement path Wr of the center point We of the wafer W1.

Thus, the Y-direction movement mechanism 214c supplies the wafer W1 to the cool air supplier 206, the cooling unit 207, and the squeegee unit 213 that are linearly aligned in the plan view.

The squeegee unit 213 and the ultraviolet irradiator 212 are arranged in a straight line with the cool air supplier 206, the cooling unit 207, and the heat shrinker 211 in the direction (Y direction) in which the cool air supplier 206, the cooling unit 207, and the heat shrinker 211 are aligned in the plan view.

That is, the center point Sc of the pressing work area As of the squeegee unit 213 and the center point Uc of the ultraviolet irradiation work area Au of the ultraviolet irradiator 212 are located on the movement path Wr of the center point We of the wafer W1 together with the center point Cc1 of the cool air supplier 206, the center point Cc2 of the cooling unit 207, and the center point He of the heat shrinker 211.

Thus, the Y-direction movement mechanism 214c supplies the wafer W1 to the cool air supplier 206, the cooling unit 207, the heat shrinker 211, the ultraviolet irradiator 212, and the squeegee unit 213 that are linearly aligned in the plan view.

In a manufacturing method for the semiconductor chip Ch (semiconductor chip manufacturing process described above), which is a manufacturing method for manufacturing the semiconductor chip Ch, the dicing control calculator 111 performs a step of forming a modified layer in the wafer W1 by emitting a laser beam to the wafer W1 from the laser irradiator 13a that emits the laser beam. Furthermore, the expansion control calculator 109 performs a step of supplying the wafer W1 to the expander 208 by the Y-direction movement mechanism 214c that supplies the wafer W1 to the expander 208 that expands the elastic sheet member W2, at least one of the cool air supplier 206 and the cooling unit 207 that cool the sheet member W2, or the heat shrinker 211 that heats and shrinks the sheet member W2 while maintaining the gap between the plurality of semiconductor chips Ch, and the squeegee unit 213 that locally presses the wafer W1, all of which are linearly aligned in the plan view. Moreover, the expansion control calculator 109 performs a step of expanding the sheet member W2 to divide the wafer W1 into the plurality of semiconductor chips Ch along the dividing line using the expander 208 linearly aligned together with the cool air supplier 206, the cooling unit 207, and the squeegee unit 213.

The semiconductor chip Ch manufactured by such a manufacturing method for the semiconductor chip Ch is manufactured by the expanding device 2 including the Y-direction movement mechanism 214c to supply the wafer W1 to the expander 208, at least one of the cool air supplier 206, the cooling unit 207, or the heat shrinker 211, and the squeegee unit 213, all of which are linearly aligned in the plan view.

### Advantageous Effects of First Embodiment

According to the first embodiment, the following advantageous effects are achieved.

According to the first embodiment, as described above, in the plan view, the expanding device 2 includes the Y-direction movement mechanism 214c to supply the wafer W1 to the expander 208, at least one of the cool air supplier 206, the cooling unit 207, or the heat shrinker 211, and the squeegee unit 213. In the plan view, the expander 208, at least one of the cool air supplier 206, the cooling unit 207, or the heat shrinker 211, and the squeegee unit 213 are linearly aligned. Accordingly, the wafer W1 is supplied to the squeegee unit 213, the expander 208, the cool air supplier 206, the cooling unit 207, and the heat shrinker 211 that are linearly aligned, using the Y-direction movement mechanism 214c such that a mechanism that conveys the wafer W1 to the squeegee unit 213, the expander 208, and at least one of the cool air supplier 206, the cooling unit 207, or the heat shrinker 211 can be achieved by using one linear movement mechanism, and thus the structure of a movement mechanism that supplies the wafer W1 between a plurality of devices such as the expander 208 and the squeegee unit 213 can be simplified.

According to the first embodiment, as described above, the expanding device 2 includes the cool air supplier 206, the cooling unit 207, and the heat shrinker 211. The expander 208 is located below the heat shrinker 211. The cool air supplier 206 and the cooling unit 207, and the expander 208 located below the heat shrinker 211 are linearly aligned in the plan view. The squeegee unit 213 is arranged in a straight line with the cool air supplier 206, the cooling unit 207, and the expander 208 in the direction in which the cool air supplier 206, the cooling unit 207, and the expander 208 are aligned in the plan view. The Y-direction movement mechanism 214c is operable to supply the wafer W1 to the cool air supplier 206, the cooling unit 207, the expander 208, and the squeegee unit 213 that are linearly aligned in the plan view. Accordingly, the expander 208 is arranged below the heat shrinker 211 such that an increase in the size of the expanding device 2 in the horizontal direction can be reduced or prevented as compared with a case in which the expander 208 is deviated from the heat shrinker 211 in the horizontal direction. Furthermore, the wafer W1 is supplied using the Y-direction movement mechanism 214c such that a mechanism that conveys the wafer W1 to the squeegee unit 213, the expander 208, the cool air supplier 206, and the cooling unit 207 can be achieved by using one linear movement mechanism, and thus the structure of the movement mechanism that supplies the wafer W1 between a plurality of devices such as the expander 208 and the squeegee unit 213 can be simplified. Consequently, an increase in the size of the expanding device 2 can be reduced or prevented, and the structure of the movement mechanism that supplies the wafer W1 between a plurality of devices such as the expander 208 and the squeegee unit 213 can be simplified.

According to the first embodiment, as described above, the expanding device 2 includes the cool air supplier 206, the cooling unit 207, and the heat shrinker 211. The expander 208 includes the ring-shaped expanding ring 281 to expand the sheet member W2 to divide the wafer W1 along the dividing line. The squeegee unit 213 is arranged inside the inner circumferential surface of the expanding ring 281. The cool air supplier 206, the cooling unit 207, and the heat shrinker 211 are linearly aligned in the plan view. The squeegee unit 213 is arranged in a straight line with the cool air supplier 206 and the cooling unit 207 in the direction in which the cool air supplier 206, the cooling unit 207, and the heat shrinker 211 are aligned in the plan view. The Y-direction movement mechanism 214c is operable to supply the wafer W1 to the cool air supplier 206, the cooling unit 207, the heat shrinker 211, and the squeegee unit 213 that are linearly aligned in the plan view. Accordingly, the squeegee unit 213 can be arranged inside the inner circumferential surface of the expanding ring 281 effectively using a space inside the inner circumferential surface of the expanding ring 281, and thus an increase in the size of the expanding device 2 can be further reduced or prevented. Furthermore, the wafer W1 is supplied using the Y-direction movement mechanism 214c such that a mechanism that conveys the wafer W1 to the squeegee unit 213, the cool air supplier 206, the cooling unit 207, and the heat shrinker 211 can be achieved by using one linear movement mechanism, and thus the structure of the movement mechanism that supplies the wafer W1 between a plurality of devices such as the expander 208 and the squeegee unit 213 can be simplified. Consequently, an increase in the size of the expanding device 2 can be reduced or prevented, and the structure of the movement mechanism that supplies the wafer W1 between a plurality of devices such as the expander 208 and the squeegee unit 213 can be simplified.

According to the first embodiment, as described above, the expander 208 and the squeegee unit 213 arranged inside the inner circumferential surface of the expanding ring 281 are arranged below the heat shrinker 211. The squeegee unit 213 is arranged in a straight line with the cool air supplier 206 and the cooling unit 207 in the direction in which the cool air supplier 206, the cooling unit 207, and the heat shrinker 211 are aligned in the plan view. The Y-direction movement mechanism 214c is operable to supply the wafer W1 to the cool air supplier 206, the cooling unit 207, the expander 208, and the squeegee unit 213 arranged inside the inner circumferential surface of the expanding ring 281 that are linearly aligned in the plan view. Accordingly, the squeegee unit 213 arranged inside the inner circumferential surface of the expanding ring 281 is arranged below the heat shrinker 211 such that an increase in the size of the expanding device 2 in the horizontal direction can be reduced or prevented as compared with a case in which the squeegee unit 213 arranged inside the inner circumferential surface of the expanding ring 281 is deviated from the heat shrinker 211 in the horizontal direction. Consequently, the structure of the movement mechanism that supplies the wafer W1 between a plurality of devices such as the expander 208 and the squeegee unit 213 can be simplified, and an increase in the size of the expanding device 2 can be further reduced or prevented.

According to the first embodiment, as described above, in addition to the cool air supplier 206, the cooling unit 207, and the heat shrinker 211, the expanding device 2 includes the ultraviolet irradiator 212 to irradiate the portion of the sheet member W2 expanded by the expander 208 that corresponds to the position of the wafer W1 with ultraviolet rays Ut. The cool air supplier 206, the cooling unit 207, and the heat shrinker 211 are linearly aligned in the plan view. The squeegee unit 213 and the ultraviolet irradiator 212 are arranged in a straight line with the cool air supplier 206, the cooling unit 207, and the heat shrinker 211 in the direction in which the cool air supplier 206, the cooling unit 207, and the heat shrinker 211 are aligned in the plan view. The Y-direction movement mechanism 214c is operable to supply the wafer W1 to the cool air supplier 206, the cooling unit 207, the heat shrinker 211, the squeegee unit 213, and the ultraviolet irradiator 212 that are linearly aligned in the plan view. Accordingly, the wafer W1 is supplied using the Y-direction movement mechanism 214c such that a mechanism that conveys the wafer W1 to the cool air supplier 206, the cooling unit 207, the heat shrinker 211, the squeegee unit 213, and the ultraviolet irradiator 212 can be achieved by using one linear movement mechanism, and thus the structure of the movement mechanism that supplies the wafer W1 between a plurality of devices such as the expander 208 and the squeegee unit 213 can be simplified.

According to the first embodiment, as described above, the expander 208 includes the expanding ring 281 to expand the sheet member W2 to divide the wafer W1 along the dividing line. The squeegee unit 213 and the ultraviolet irradiator 212 are arranged inside the inner circumferential surface of the expanding ring 281. The squeegee unit 213 and the ultraviolet irradiator 212 are arranged in a straight line with the cool air supplier 206, the cooling unit 207, and the heat shrinker 211 in the direction in which the cool air supplier 206, the cooling unit 207, and the heat shrinker 211 are aligned in the plan view. The Y-direction movement mechanism 214c is operable to supply the wafer W1 to the cool air supplier 206, the cooling unit 207, the heat shrinker 211, and the squeegee unit 213 and the ultraviolet irradiator 212 arranged inside the inner circumferential surface of the expanding ring 281 that are linearly aligned in the plan view. Accordingly, the squeegee unit 213 and the ultraviolet irradiator 212 can be arranged inside the inner circumferential surface of the expanding ring 281 effectively using the space inside the inner circumferential surface of the expanding ring 281, and thus an increase in the size of the expanding device 2 can be further reduced or prevented. Furthermore, the wafer W1 is supplied using the Y-direction movement mechanism 214c such that a mechanism that conveys the wafer W1 to the squeegee unit 213, the ultraviolet irradiator 212, the cool air supplier 206, the cooling unit 207, and the heat shrinker 211 can be achieved by using one linear movement mechanism, and thus the structure of the movement mechanism that supplies the wafer W1 between a plurality of devices such as the expander 208 and the squeegee unit 213 can be simplified, and an increase in the size of the expanding device 2 can be further reduced or prevented.

According to the first embodiment, as described above, in addition to the cool air supplier 206 and the cooling unit 207, the expanding device 2 includes the clamp unit 214 including the gripper 214a to hold the ring-shaped member W3 that is attached to the sheet member W2 while surrounding the wafer W1, and the Y-direction movement mechanism 214c to move the gripper 214a holding the ring-shaped member W3. In the plan view, the center point Cc1 and the center point Cc2 of the cooling work areas Ac1 and Ac2 in which the sheet member W2 is cooled by the cool air supplier 206 and the cooling unit 207 and the center point Sc of the pressing work area As in which the squeegee unit 213 presses the wafer W1 via the sheet member W2 are located on the movement path Wr of the center point We of the wafer W1 held by the gripper 214a when the gripper 214a is moved by the Y-direction movement mechanism 214c. Accordingly, when the sheet member W2 is cooled by the cool air supplier 206 and the cooling unit 207, and when the wafer W1 is pressed by the squeegee unit 213, the center points Cc1 and Cc2 of the cooling work areas Ac1 and Ac2 and the center point Sc of the pressing work area As are not deviated in position in the X direction with respect to the wafer W1 held by the gripper 214a, and thus even without a separate linear movement mechanism extending in the X direction, both the cooling work by the cool air supplier 206 and the cooling unit 207 and the pressing work by the squeegee unit 213 can be performed. Consequently, an increase in the number of movement mechanisms required in the expanding device 2 can be reduced or prevented, and thus an increase in the size of the expanding device 2 can be further reduced or prevented.

According to the first embodiment, as described above, the manufacturing method for the semiconductor chip Ch includes a step of supplying the wafer W1 to the expander 208 operable to expand the elastic sheet member W2 by the Y-direction movement mechanism 214c operable to supply the wafer W1 to the expander 208, at least one of the cool air supplier 206 and the cooling unit 207 operable to cool the sheet member W2, or the heat shrinker 211 operable to heat and shrink the sheet member W2 while maintaining the gap between the plurality of semiconductor chips Ch, and the squeegee unit 213 operable to locally press the wafer W1. The expander 208, at least one of the cool air supplier 206, the cooling unit 207, or the heat shrinker 211, and the squeegee unit 213 are linearly aligned in the plan view. Accordingly, the wafer W1 is supplied to the squeegee unit 213, the expander 208, and at least one of the cool air supplier 206, the cooling unit 207, or the heat shrinker 211 that are linearly aligned, using the Y-direction movement mechanism 214c such that a mechanism that conveys the wafer W1 to the squeegee unit 213, the expander 208, and at least one of the cool air supplier 206, the cooling unit 207, or the heat shrinker 211 can be achieved by using one linear movement mechanism, and thus the manufacturing method for the semiconductor chip Ch can be obtained in which the structure of the movement mechanism that supplies the wafer W1 between a plurality of devices such as the expander 208 and the squeegee unit 213 can be simplified.

According to the first embodiment, as described above, the semiconductor chip Ch is manufactured by the expanding device 2 including the Y-direction movement mechanism 214c to supply the wafer W1 to the expander 208, at least one of the cool air supplier 206, the cooling unit 207, or the heat shrinker 211, and the squeegee unit 213. In the expanding device 2, the expander 208, at least one of the cooling unit 207 or the heat shrinker 211, and the squeegee unit 213 are linearly aligned in the plan view. Accordingly, the wafer W1 is supplied to the squeegee unit 213, the expander 208, and at least one of the cooling unit 207 or the heat shrinker 211 that are linearly aligned, using the Y-direction movement mechanism 214c such that a mechanism that conveys the wafer W1 to the squeegee unit 213, the expander 208, and at least one of the cooling unit 207 or the heat shrinker 211 can be achieved by using one linear movement mechanism, and thus the semiconductor chip Ch can be obtained by the expanding device 2 that enables a simple structure of the movement mechanism that supplies the wafer W1 between a plurality of devices such as the expander 208 and the squeegee unit 213.

### Second Embodiment

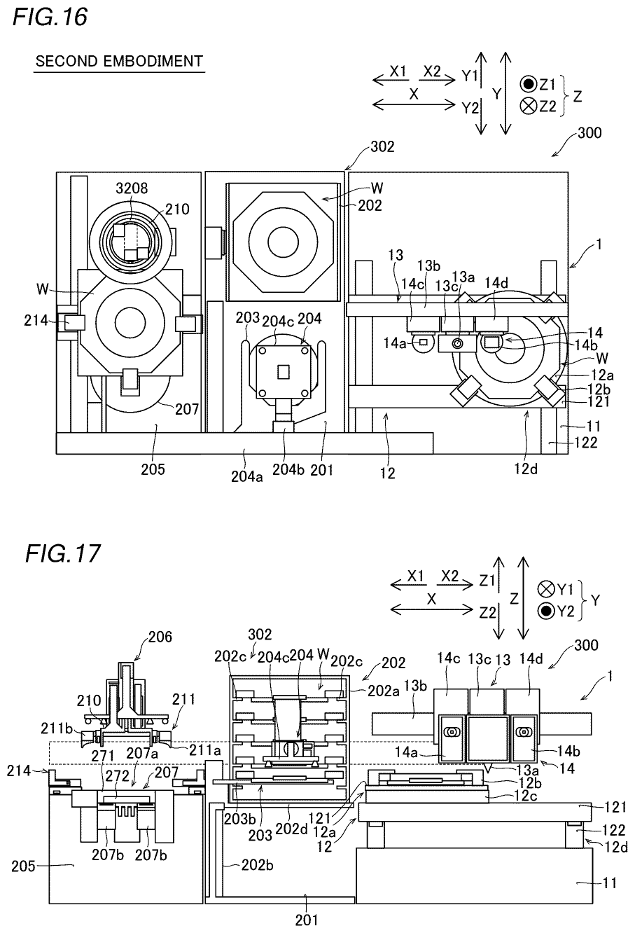

The configuration of a semiconductor wafer processing apparatus 300 according to a second embodiment is now described with reference to FIGS. 16 to 25. In the second embodiment, a squeegee unit 3213 is arranged outside an expanding ring 3281, unlike the first embodiment. In the second embodiment, detailed description of the same or similar configurations as those of the first embodiment is omitted.

### Semiconductor Wafer Processing Apparatus

As shown in FIGS. 16 and 17, the semiconductor wafer processing apparatus 300 is an apparatus that processes a wafer W1 provided on a wafer ring structure W.

The semiconductor wafer processing apparatus 300 includes a dicing device 1 and an expanding device 302. An upward-downward direction is defined as a Z direction, an upward direction is defined as a Z1 direction, and a downward direction is defined as a Z2 direction. In a horizontal direction perpendicular to the Z direction, a direction in which the dicing device 1 and the expanding device 302 are aligned is defined as an X direction, a direction from the dicing device 1 toward the expanding device 302 in the X direction is defined as an X1 direction, and a direction from the expanding device 302 toward the dicing device 1 in the X direction is defined as an X2 direction. A direction perpendicular to the X direction in the horizontal direction is defined as a Y direction, one direction in the Y direction is defined as a Y1 direction, and the other direction in the Y direction is defined as a Y2 direction.

### Dicing Device

The dicing device 1 emits a laser beam having a wavelength transmissive to the wafer W1 along a dividing line (street Ws) to form a modified layer.

Specifically, the dicing device 1 includes a base 11, a chuck table unit 12, a laser 13, and an imager 14.

### Expanding Device

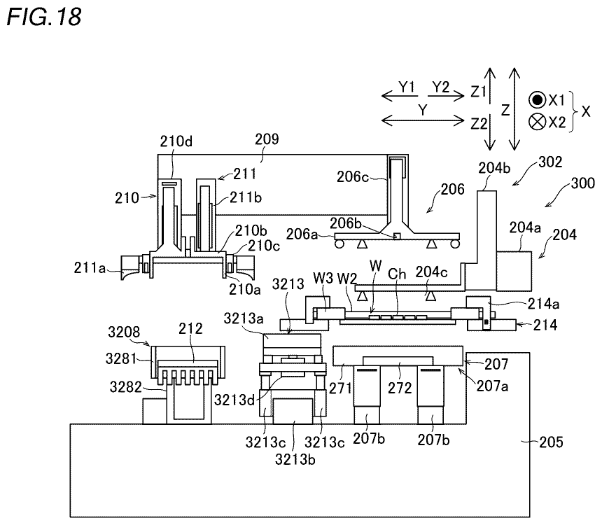

As shown in FIGS. 17 and 18, the expanding device 302 divides the wafer W1 to form a plurality of semiconductor chips Ch.

The expanding device 302 includes a base 201, a cassette unit 202, a lift-up hand unit 203, a suction hand unit 204, a base 205, a cool air supplier 206, a cooling unit 207, an expander 3208, a base 209, an expansion maintaining member 210, a heat shrinker 211, an ultraviolet irradiator 212, a squeegee unit 3213, and a clamp unit 214.

### Expander

The expander 3208 expands a sheet member W2 of the wafer ring structure W to divide the wafer W1 along the dividing line.

Specifically, the expander 3208 includes the expanding ring 3281 and a Z-direction movement mechanism 3282.

The expanding ring 3281 expands the sheet member W2 by supporting the sheet member W2 from the Z2 direction side. The expanding ring 3281 has a ring shape in a plan view. The Z-direction movement mechanism 3282 moves the expanding ring 3281 in the Z1 direction or the Z2 direction. The Z-direction movement mechanism 3282 includes a linear conveyor module, or a ball screw and a drive including a motor with an encoder, for example. The Z-direction movement mechanism 3282 is attached to the base 201.

### Squeegee Unit

The squeegee unit 3213 further divides the wafer W1 along the modified layer by pressing the wafer W1 from the Z2 direction side after the sheet member W2 is expanded. Specifically, the squeegee unit 3213 includes a press 3213a, an X-direction movement mechanism 3213b, a Z-direction movement mechanism 3213c, and a rotation mechanism 3213d.

The prese 3213a generates a bending stress in the wafer W1 to divide the wafer W1 along the modified layer by being moved by the rotation mechanism 3213d and the X-direction movement mechanism 3213b while pressing the wafer W1 from the Z2 direction side via the sheet member W2 after being moved in the Z1 direction by the Z-direction movement mechanism 3213c. The press 3213a is a squeegee. The press 3213a is attached to an end of the rotation mechanism 3213d on the Z1 direction side. The Z-direction movement mechanism 3213c moves the rotation mechanism 3213d in the Z1 direction or the Z2 direction. The Z-direction movement mechanism 3213c includes a cylinder, for example. The Z-direction movement mechanism 3213c is attached to an end of the X-direction movement mechanism 3213b on the Z1 direction side. The X-direction movement mechanism 3213b includes a linear conveyor module, or a ball screw and a drive including a motor with an encoder, for example. The X-direction movement mechanism 3213b is attached to an end of the base 205 on the Z1 direction side.

In the squeegee unit 3213, the prese 3213a divides the wafer W1 by being moved in the Y direction by the X-direction movement mechanism 3213b while pressing the wafer W1 from the Z2 direction side via the sheet member W2 after being moved in the Z1 direction by the Z-direction movement mechanism 3213c. Furthermore, in the squeegee unit 3213, after the press 3213a finishes moving in the Y direction, the press 3213a is rotated 90 degrees by the rotation mechanism 3213d. Moreover, in the squeegee unit 3213, the press 3213a divides the wafer W1 by being moved in the X direction by the X-direction movement mechanism 3213b while pressing the wafer W1 from the Z2 direction side via the sheet member W2 after being rotated 90 degrees.

### Control Configuration of Semiconductor Wafer Processing Apparatus

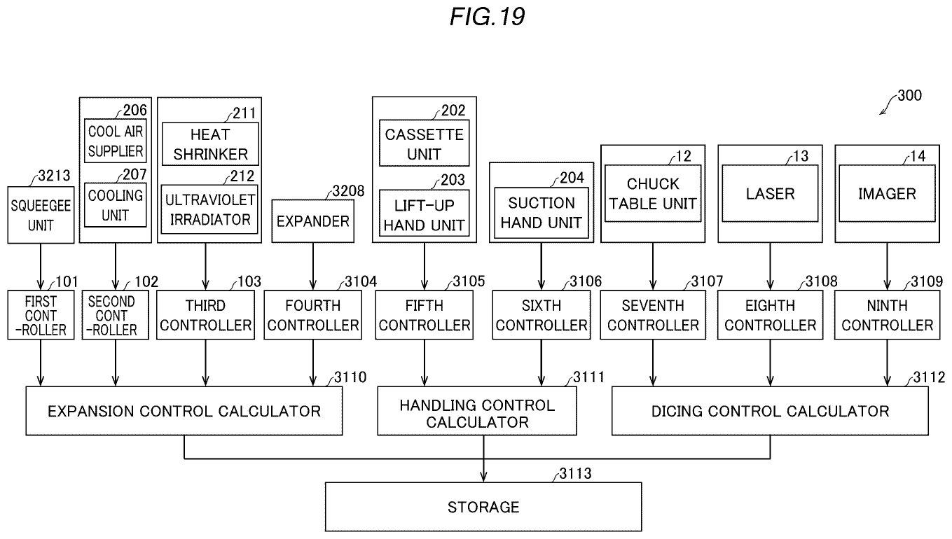

As shown in FIG. 19, the semiconductor wafer processing apparatus 300 includes a first controller 101, a second controller 102, a third controller 103, a fourth controller 3104, a fifth controller 3105, a sixth controller 3106, a seventh controller 3107, an eighth controller 3108, a ninth controller 3109, an expansion control calculator 3110, a handling control calculator 3111, a dicing control calculator 3112, and a storage 3113. The first controller 101, the second controller 102, the third controller 103, the fifth controller 3105, the sixth controller 3106, the seventh controller 3107, the eighth controller 3108, the ninth controller 3109, the expansion control calculator 3110, the handling control calculator 3111, the dicing control calculator 3112, and the storage 3113 have the same configurations as the first controller 101, the second controller 102, the third controller 103, the fourth controller 104, the fifth controller 105, the sixth controller 106, the seventh controller 107, the eighth controller 108, the expansion control calculator 109, the handling control calculator 110, the dicing control calculator 111, and the storage 112 according to the first embodiment, respectively, and thus description thereof is omitted.

The fourth controller 3104 controls the expander 3208. The fourth controller 104 includes a CPU and a storage including a ROM and a RAM, for example. The fourth controller 3104 may include, as a storage, an HDD that retains stored information even after the voltage is cut off, for example.

### Semiconductor Chip Manufacturing Process

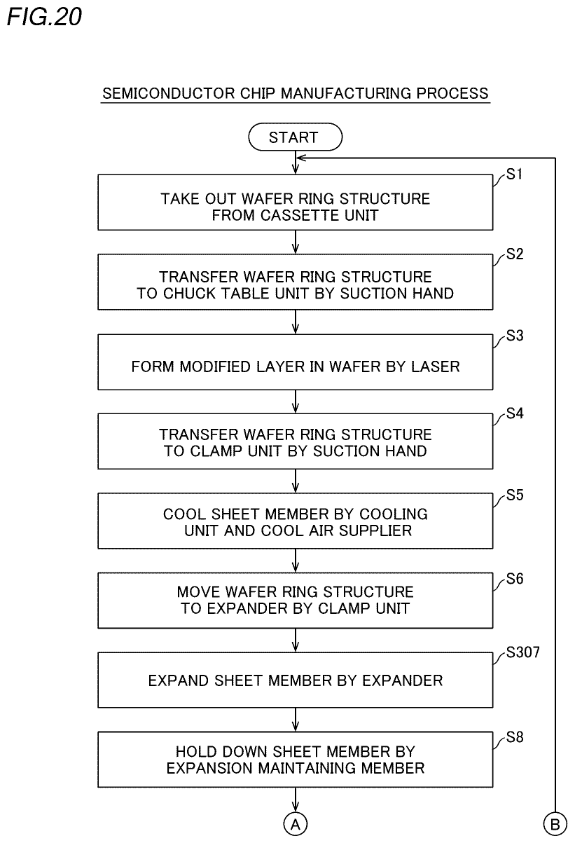

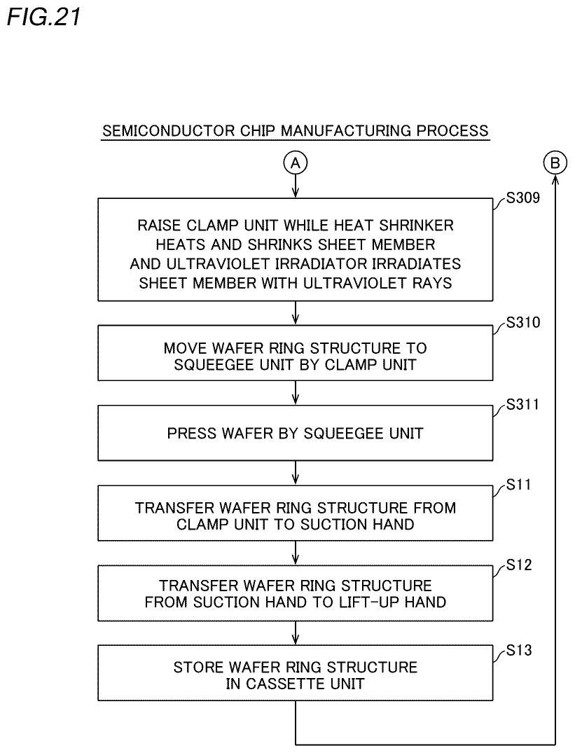

The overall operation of the semiconductor wafer processing apparatus 300 is described below with reference to FIGS. 20 and 21.

Process operations in step S1 to step S6, step S8, and step S11 are the same as the process operations in step S1 to step S6, step S8, and step S11 in the semiconductor chip manufacturing process according to the first embodiment, respectively, and thus description thereof is omitted.

In step S307, the sheet member W2 is expanded by the expander 3208. That is, the expanding ring 3281 is moved in the Z1 direction by the Z-direction movement mechanism 3282. The wafer ring structure W is moved in the Z2 direction by a Z-direction movement mechanism 214b while being held by the clamp unit 214. Then, the sheet member W2 is expanded by contacting the expanding ring 3281 and being pulled by the expanding ring 3281. Thus, the wafer W1 is divided along the dividing line (modified layer).

As shown in FIG. 21, in step S309, while the heat shrinker 211 heats and shrinks the sheet member W2 and the ultraviolet irradiator 212 irradiates the sheet member W2 with ultraviolet rays Ut, the clamp unit 214 is raised. At this time, an intake 210c takes in air in the vicinity of the heated sheet member W2. In step S310, the wafer ring structure W is moved to the squeegee unit 3213 by the clamp unit 214. That is, the wafer ring structure W is moved in the Y2 direction by a Y-direction movement mechanism 214c while being held by the clamp unit 214.

In step S311, after the wafer ring structure W is moved to the squeegee unit 3213, the wafer W1 is pressed by the squeegee unit 3213. Thus, the wafer W1 is further divided by the squeegee unit 3213.

Arrangement Positions of Cool Air Supplier, Cooling Unit, Expander, Expansion Maintaining Member, Heat Shrinker, Ultraviolet Irradiator, and Squeegee Unit

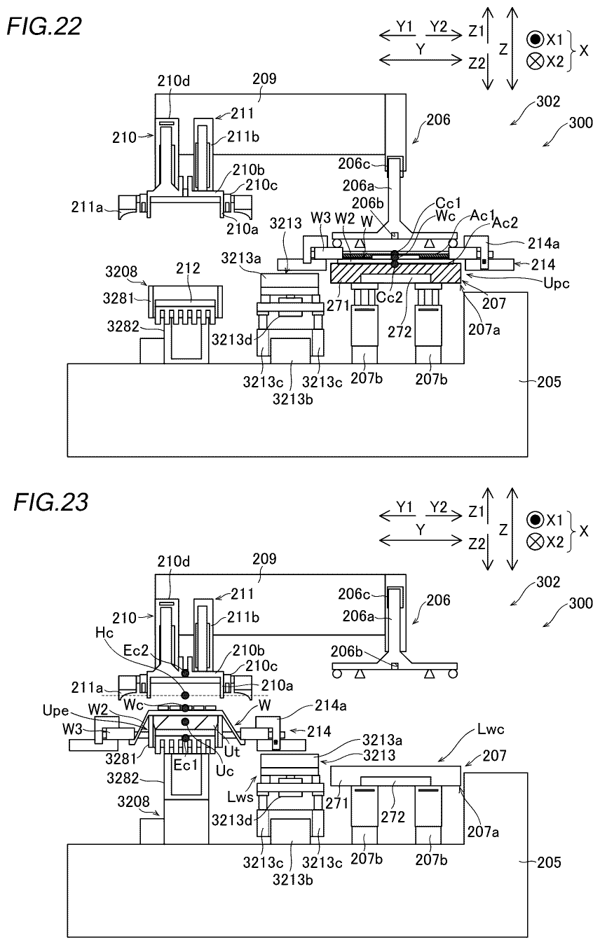

The arrangement positions of the cool air supplier 206, the cooling unit 207, the expander 3208, the expansion maintaining member 210, the heat shrinker 211, the ultraviolet irradiator 212, and the squeegee unit 3213 in the plan view are now described with reference to FIGS. 22 to 25.

As shown in FIG. 22, the expanding device 2 includes the cool air supplier 206, the cooling unit 207, the expander 3208, the expansion maintaining member 210, the heat shrinker 211, the ultraviolet irradiator 212, the squeegee unit 3213, and the clamp unit 214. In FIGS. 22 to 24, the suction hand unit 204 is not shown for the convenience of illustration.

As shown in FIGS. 22 and 23, the cool air supplier 206 cools the sheet member W2 before the sheet member W2 is expanded by the expander 3208. Specifically, the cool air supplier 206 includes a supplier main body 206a, a cool air supply port 206b, and a movement mechanism 206c.

In the cool air supplier 206, the supplier main body 206a is lowered to a lowered position by the movement mechanism 206c, and then cool air is discharged through the cool air supply port 206b. At this time, the cool air discharged through the cool air supply port 206b is accumulated in a cooling work area Ac1 on the wafer W1 side (inside) of a ring-shaped member W3 of the wafer ring structure W, and thus a portion of the sheet member W2 corresponding to the cooling work area Ac1 is cooled. In the horizontal direction perpendicular to the Z direction, the center of the cooling work area Ac1 of the cool air supplier 206 is a center point Cc1.

After the cool air supplier 206 finishes cooling the portion of the sheet member W2 corresponding to the cooling work area Ac1, a cool air supply from the cool air supplier 206 is stopped, and the supplier main body 206a is raised to a raised position by the movement mechanism 206c.

The cool air supplier 206 can move up and down so as not to interfere with the expander 3208, the heat shrinker 211, the squeegee unit 3213, and the clamp unit 214. Specifically, the cool air supplier 206 can move down to a working position at which the cool air supplier 206 does not interfere with the adjacent expander 3208, heat shrinker 211, and squeegee unit 3213. The cool air supplier 206 can move up to a retracted position at which the cool air supplier 206 does not interfere with the adjacent expander 3208, heat shrinker 211, and squeegee unit 3213.

### Cooling Unit

The cooling unit 207 cools the sheet member W2 before the sheet member W2 is expanded by the expander 3208. Specifically, the cooling unit 207 includes a cooling member 207a including a cooling body 271 and a Peltier element 272, and a Z-direction movement mechanism 207b.

In the cooling unit 207, the cooling member 207a is raised to a raised position Upc by the Z-direction movement mechanism 207b, and then the cooling body 271 is cooled by the Peltier element 272 such that a portion of the sheet member W2 that contacts the cooling body 271 in the Z direction is cooled. Thus, the portion of the sheet member W2 that contacts the cooling body 271 in the Z direction is a cooling work area Ac2 of the cooling unit 207. In the horizontal direction perpendicular to the Z direction, the center of the cooling work area Ac2 of the cooling unit 207 is a center point Cc2. In the Z direction, the center points Cc1 and Cc2 overlap each other.

After the cooling unit 207 finishes cooling a portion of the sheet member W2 corresponding to the cooling work area Ac2, the cooling by the cooling unit 207 is stopped, and the cooling member 207a is lowered to a lowered position Lwc by the Z-direction movement mechanism 207b.

The cooling unit 207 can move up and down so as not to interfere with the expander 3208, the heat shrinker 211, the squeegee unit 3213, and the clamp unit 214. Specifically, the cooling unit 207 can move up to a working position (raised position Upc) at which the cooling unit 207 does not interfere with the adjacent expander 3208, heat shrinker 211 and squeegee unit 3213, and the clamp unit 214. The cooling unit 207 can move down to are tracted position (lowered position Lwc) at which the cooling unit 207 does not interfere with the adjacent expander 3208, heat shrinker 211 and squeegee unit 3213, and the clamp unit 214.

### Expander

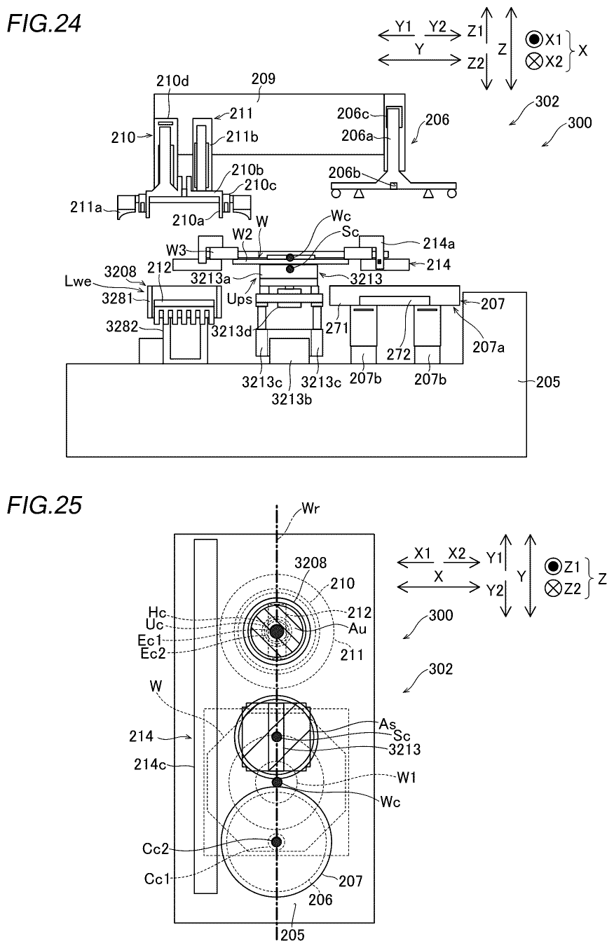

As shown in FIGS. 23 and 24, the expander 3208 divides the wafer W1 into the plurality of semiconductor chips Ch along the dividing line (street Ws) by expanding the elastic sheet member W2. Specifically, the expander 3208 includes the expanding ring 3281 and the Z-direction movement mechanism 3282. The expanding ring 281 is a ring-shaped member that divides the wafer W1 along the dividing line by expanding the sheet member W2.

The expander 3208 is arranged below the heat shrinker 211. That is, the expanding ring 3281 is arranged below the heat shrinker 211. In the plan view, the center of the ring-shaped expanding ring 3281 is a center point Ec1.

In the expander 3208, the expanding ring 3281 is raised to an upper position Upe by the Z-direction movement mechanism 3282 to expand the sheet member W2. Furthermore, in the expander 3208, after the expanding ring 3281 finishes expanding the sheet member W2, the expanding ring 3281 is lowered to a lowered position Lwe by the Z-direction movement mechanism 3282.

The expander 3208 can move up and down so as not to interfere with the squeegee unit 3213 and the clamp unit 214. Specifically, the expander 3208 can move up to a working position (upward position Upe) at which the expander 3208 does not interfere with the adjacent squeegee unit 3213 and the clamp unit 214. The expander 3208 can move down to a retracted position (lowered position Lwe) at which the expander 3208 does not interfere with the adjacent squeegee unit 3213 and the clamp unit 214.

### Expansion Maintaining Member

The expansion maintaining member 210 includes a pressing ring 210a, a lid 210b, an intake 210c, and a Z-direction movement mechanism 210d. The pressing ring 210a is a ring-shaped member. In the plan view, the center of the ring-shaped pressing ring 210a is a center point Ec2. The configuration of the expansion maintaining member 210 is the same as the configuration of the expansion maintaining member 210 according to the first embodiment, and thus description thereof is omitted.

### Heat Shrinker

The heat shrinker 211 heats and shrinks the sheet member W2 expanded by the expander 3208 while maintaining a gap between the plurality of semiconductor chips Ch. Specifically, the heat shrinker 211 includes a heating ring 211a and a Z-direction movement mechanism 211b. The heating ring 211a has a ring shape in the plan view. In the plan view, the center of the ring-shaped heating ring 211a is a center point Hc. The configuration of the heat shrinker 211 is the same as the configuration of the heat shrinker 211 according to the first embodiment, and thus description thereof is omitted.

### Ultraviolet Irradiator

As shown in FIGS. 24 and 25, the ultraviolet irradiator 212 irradiates a portion of the sheet member W2 expanded by the expander 3208 that corresponds to the position of the wafer W1 with ultraviolet rays Ut. Specifically, the ultraviolet irradiator 212 includes an ultraviolet illuminator. The ultraviolet irradiator 212 is arranged inside the inner circumferential surface of the expanding ring 3281 in the plan view.

The ultraviolet irradiator 212 irradiates the sheet member W2 corresponding to the position of the wafer W1 with ultraviolet rays Ut without moving. That is, an ultraviolet irradiation work area Au in which ultraviolet rays are radiated by the ultraviolet irradiator 212 has a circular shape in the plan view. In the plan view, the center of the ultraviolet irradiation work area Au is a center point Uc. In the Z direction, the center points Hc, Ecd, Ec2, and Uc overlap each other. In FIG. 25, the sizes of points showing the center point Hc, the center point Ec1, the center point Ec2, the center point Uc, and the center point Sc are different from each other for the convenience of illustration.

### Squeegee Unit

The squeegee unit 3213 locally presses the wafer W1 after the expander 3208 expands the sheet member W2 to divide the wafer W1 into the plurality of semiconductor chips Ch. Specifically, the squeegee unit 3213 includes the press 3213a, the X-direction movement mechanism 3213b, the Z-direction movement mechanism 3213c, and the rotation mechanism 3213d.

The squeegee unit 3213 is arranged between the expanding ring 281 and the cooling unit 207 on the base 205. In the squeegee unit 3213, when the press 3213a is moved in the Y1 direction from the Y2 direction side by the X-direction movement mechanism 3213b, the press 3213a locally presses the sheet member W2 corresponding to the position of the wafer W1. In the squeegee unit 3213, when the press 3213a is moved in the X1 direction from the X2 direction side by the X-direction movement mechanism 3213b, the press 3213a locally presses the sheet member W2 corresponding to the position of the wafer W1. Thus, a pressing work area As in which the squeegee unit 3213 locally presses the wafer W1 has a cross shape in the plan view. In the plan view, the center of the pressing work area As is a center point Sc.

In the squeegee unit 3213, the press 3213a is raised to a raised position Ups by the Z-direction movement mechanism 3213c to locally press the wafer W1. Furthermore, in the squeegee unit 3213, after the press 3213a finishes locally pressing the wafer W1, the press 3213a is lowered to a lowered position Lws (see FIG. 23) by the Z-direction movement mechanism 3213c.

The squeegee unit 3213 can move up and down so as not to interfere with the expander 3208, the cooling unit 207, and the clamp unit 214. Specifically, the squeegee unit 3213 can move up to a working position (upward position Ups) at which the squeegee unit 3213 does not interfere with the adjacent expander 3208 and cooling unit 207, and the clamp unit 214. The squeegee unit 3213 can move down to a retracted position (lowered position Lws) at which the squeegee unit 3213 does not interfere with the adjacent expander 3208 and cooling unit 207, and the clamp unit 214.

### Clamp Unit

The clamp unit 214 holds the ring-shaped member W3 of the wafer ring structure W. Specifically, the clamp unit 214 includes a gripper 214a, the Z-direction movement mechanism 214b, and the Y-direction movement mechanism 214c. The Z-direction movement mechanism 214b and the Y-direction movement mechanism 214c are common conveyance mechanisms for conveying the wafer W1 to the cool air supplier 206, the cooling unit 207, the expander 3208, the expansion maintaining member 210, the heat shrinker 211, the ultraviolet irradiator 212, and the squeegee unit 3213.

### Linear Positional Relationship

As shown in FIG. 25, in the expanding device 2 according to the second embodiment, the expander 3208, at least one of the cool air supplier 206, the cooling unit 207, or the heat shrinker 211, and the squeegee unit 3213 are linearly aligned in the plan view. Thus, the Y-direction movement mechanism 214c supplies the wafer W1 to the expander 3208, at least one of the cool air supplier 206, the cooling unit 207, or the heat shrinker 211, and the squeegee unit 3213 that are linearly aligned in the plan view.

The cooling unit 207 is arranged below the cool air supplier 206. The expander 3208 is arranged below the heat shrinker 211. The ultraviolet irradiator 212 is arranged inside the inner circumferential surface of the expanding ring 281. The expander 3208, and the ultraviolet irradiator 212 arranged inside the inner circumferential surface of the expanding ring 281 are arranged below the heat shrinker 211. The squeegee unit 3213 is arranged between the cooling unit 207 and the expanding ring 281.

The cool air supplier 206, the cooling unit 207, and the expander 3208 arranged below the heat shrinker 211 are linearly aligned in the plan view. In addition, the squeegee unit 3213 is arranged in a straight line with the cool air supplier 206, the cooling unit 207, and the expander 3208 in a direction (Y direction) in which the cool air supplier 206, the cooling unit 207, and the expander 3208 are aligned in the plan view.

That is, the center point Sc of the pressing work area As of the squeegee unit 3213 is located on a movement path Wr of the center point We of the wafer W1 together with the center point Cc1 of the cool air supplier 206, the center point Cc2 of the cooling unit 207, and the center point Ec1 of the expander 3208. The movement path Wr of the center point We of the wafer W1 refers to a path along which the center point We of the wafer W1 held by the gripper 214a moves when the gripper 214a is moved by the Y-direction movement mechanism 214c. The movement path Wr of the center point We of the wafer W1 extends along the Y direction.

The cool air supplier 206, the cooling unit 207, and the heat shrinker 211 are linearly aligned in the plan view. The squeegee unit 3213 is arranged in a straight line with the cool air supplier 206 and the cooling unit 207 in a direction (Y direction) in which the cool air supplier 206, the cooling unit 207, and the heat shrinker 211 are aligned in the plan view.

That is, the center point Sc of the pressing work area As of the squeegee unit 3213 is located on the movement path Wr of the center point We of the wafer W1 together with the center point Cc1 of the cool air supplier 206, the center point Cc2 of the cooling unit 207, and the center point He of the heat shrinker 211.

Thus, the Y-direction movement mechanism 214c supplies the wafer W1 to the cool air supplier 206, the cooling unit 207, the heat shrinker 211, and the squeegee unit 3213 that are linearly aligned in the plan view.

The squeegee unit 3213 is arranged in a straight line with the cool air supplier 206 and the cooling unit 207 in the direction (Y direction) in which the cool air supplier 206, the cooling unit 207, and the heat shrinker 211 are aligned in the plan view.

That is, the center point Cc1 of the cooling work area Ac1 in which the sheet member W2 is cooled by the cool air supplier 206, the center point Cc2 of the cooling work area Ac2 in which the sheet member W2 is cooled by the cooling unit 207, and the center point Sc of the pressing work area As in which the squeegee unit 3213 presses the wafer W1 via the sheet member W2 are located on the movement path Wr of the center point We of the wafer W1 in the plan view.

Thus, the Y-direction movement mechanism 214c supplies the wafer W1 to the cool air supplier 206, the cooling unit 207, and the squeegee unit 213 that are linearly aligned in the plan view.

The squeegee unit 3213 and the ultraviolet irradiator 212 is arranged in a straight line with the cool air supplier 206, the cooling unit 207, and the heat shrinker 211 in the direction (Y direction) in which the cool air supplier 206, the cooling unit 207, and the heat shrinker 211 are aligned in the plan view.

That is, the center point Sc of the pressing work area As of the squeegee unit 3213 and the center point Uc of the ultraviolet irradiation work area Au of the ultraviolet irradiator 212 are located on the movement path Wr of the center point We of the wafer W1 together with the center point Cc1 of the cool air supplier 206, the center point Cc2 of the cooling unit 207, and the center point He of the heat shrinker 211.

Thus, the Y-direction movement mechanism 214c supplies the wafer W1 to the cool air supplier 206, the cooling unit 207, the heat shrinker 211, the ultraviolet irradiator 212, and the squeegee unit 213 that are linearly aligned in the plan view. The remaining configurations of the second embodiment are similar to those of the first embodiment, and thus description thereof is omitted.

### Advantageous Effects of Second Embodiment

According to the second embodiment, the following advantageous effects are achieved.

According to the second embodiment, similarly to the first embodiment, the expanding device 302 includes the Y-direction movement mechanism 214c to supply the wafer W1 to the expander 3208, the cool air supplier 206, at least one of the cooling unit 207 or the heat shrinker 211, and the squeegee unit 3213 that are linearly aligned in the plan view. Accordingly, the structure of a movement mechanism that supplies the wafer W1 between a plurality of devices such as the expander 3208 and the squeegee unit 3213 can be simplified. The remaining advantageous effects of the second embodiment are similar to those of the first embodiment, and thus description thereof is omitted.

### MODIFIED EXAMPLES

The embodiments disclosed this time must be considered as illustrative in all points and not restrictive. The scope of the present disclosure is not shown by the above description of the embodiments but by the scope of claims for patent, and all modifications (modified examples) within the meaning and scope equivalent to the scope of claims for patent are further included.

For example, while the example in which the expander 208 (3208) is arranged below the heat shrinker 211 (heater) has been shown in each of the aforementioned first and second embodiments, the present disclosure is not restricted to this. In the present disclosure, the expander may not be arranged below the heater.

While the example in which the cool air supplier 206 and the cooling unit 207 (cooler), and the expander 208 (3208) arranged below the heat shrinker 211 (heater) are linearly aligned in the plan view has been shown in each of the aforementioned first and second embodiments, the present disclosure is not restricted to this. In the present disclosure, the cooler and the expander arranged below the heater may not be linearly aligned in the plan view.

While the example in which the ultraviolet irradiator 212 is arranged inside the inner circumferential surface of the expanding ring 281 (3281) has been shown in each of the aforementioned first and second embodiments, the present disclosure is not restricted to this. In the present disclosure, the ultraviolet irradiator may not be arranged inside the inner circumferential surface of the expanding ring.

While the example in which the expanding device 2 (302) includes the ultraviolet irradiator 212 has been shown in each of the aforementioned first and second embodiments, the present disclosure is not restricted to this. In the present disclosure, the expanding device may not include the ultraviolet irradiator.

What is claimed is:

1. An expanding device comprising:
an expander configured to expand an elastic sheet member to divide a wafer into a plurality of semiconductor chips along a dividing line;
at least one of a cooler configured to cool the sheet member before the sheet member is expanded by the expander or a heater configured to heat and shrink the sheet member expanded by the expander while maintaining a gap between the plurality of semiconductor chips;
a squeegee configured to locally press the wafer after the expander expands the sheet member to divide the wafer into the plurality of semiconductor chips; and
a movement mechanism configured to supply the wafer to the expander, at least one of the cooler or the heater, and the squeegee; wherein
the expander, at least one of the cooler or the heater, and the squeegee are linearly aligned in a plan view.

2. The expanding device according to claim 1, comprising:
both the cooler and the heater; wherein
the expander is below the heater;
the cooler and the expander below the heater are linearly aligned in the plan view;
the squeegee is in a straight line with the cooler and the expander in a direction in which the cooler and the expander are aligned in the plan view; and
the movement mechanism is configured to supply the wafer to the cooler, the expander, and the squeegee that are linearly aligned in the plan view.

3. The expanding device according to claim 1, comprising:
both the cooler and the heater; wherein
the expander includes an expanding ring having a ring shape configured to expand the sheet member to divide the wafer along the dividing line;
the squeegee is inside an inner circumferential surface of the expanding ring;
the cooler and the heater are linearly aligned in the plan view;
the squeegee is in a straight line with the cooler in a direction in which the cooler and the heater are aligned in the plan view; and
the movement mechanism is configured to supply the wafer to the cooler, the heater, and the squeegee that are linearly aligned in the plan view.

4. The expanding device according to claim 3, wherein
the expander and the squeegee inside the inner circumferential surface of the expanding ring are below the heater;
the squeegee is in a straight line with the cooler in the direction in which the cooler and the heater are aligned in the plan view; and
the movement mechanism is configured to supply the wafer to the cooler, the expander, and the squeegee inside the inner circumferential surface of the expanding ring that are linearly aligned in the plan view.

5. The expanding device according to claim 1, further comprising:
in addition to the cooler and the heater, an ultraviolet irradiator configured to irradiate a portion of the sheet member expanded by the expander that corresponds to a position of the wafer with ultraviolet rays; wherein
the cooler and the heater are linearly aligned in the plan view;
the squeegee and the ultraviolet irradiator are in a straight line with the cooler and the heater in a direction in which the cooler and the heater are aligned in the plan view; and
the movement mechanism is configured to supply the wafer to the cooler, the heater, the squeegee, and the ultraviolet irradiator that are linearly aligned in the plan view.

6. The expanding device according to claim 5, wherein
the expander includes an expanding ring configured to expand the sheet member to divide the wafer along the dividing line;
the squeegee and the ultraviolet irradiator are inside an inner circumferential surface of the expanding ring;
the squeegee and the ultraviolet irradiator are in a straight line with the cooler and the heater in the direction in which the cooler and the heater are aligned in the plan view; and
the movement mechanism is configured to supply the wafer to the cooler, the heater, the squeegee, and the ultraviolet irradiator, the cooler, the heater, the squeegee, and the ultraviolet irradiator being linearly aligned in the plan view, the squeegee and the ultraviolet irradiator being inside the inner circumferential surface of the expanding ring.

7. The expanding device according to claim 1, further comprising:
in addition to the cooler, a clamp including a gripper configured to hold a ring-shaped member that is attached to the sheet member while surrounding the wafer, and a linear movement mechanism as the movement mechanism configured to move the gripper holding the ring-shaped member; wherein
in the plan view, a center of a cooling work area in which the sheet member is cooled by the cooler and a center of a pressing work area in which the squeegee presses the wafer via the sheet member are on a movement path of a center point of the wafer held by the gripper when the gripper is moved by the linear movement mechanism; and
the linear movement mechanism is configured to supply the wafer to the cooler, the expander, and the squeegee that are linearly aligned in the plan view.

8. A semiconductor chip manufacturing method comprising:
forming a modified layer in a wafer including a plurality of semiconductor chips by emitting a laser beam to the wafer from a laser irradiator operable to emit the laser beam;
supplying the wafer to an expander configured to expand an elastic sheet member by a movement mechanism operable to supply the wafer to the expander, at least one of a cooler operable to cool the sheet member or a heater operable to heat and shrink the sheet member while maintaining a gap between the plurality of semiconductor chips, and a squeegee configured to locally press the wafer, the expander, at least one of the cooler or the heater, and the squeegee being linearly aligned in a plan view; and
expanding the sheet member to divide the wafer into the plurality of semiconductor chips along a dividing line by the expander.

9. A semiconductor chip manufactured by an expanding device, the expanding device comprising:
an expander configured to expand an elastic sheet member to divide a wafer into a plurality of semiconductor chips along a dividing line;
at least one of a cooler configured to cool the sheet member before the sheet member is expanded by the expander or a heater to heat and shrink the sheet member expanded by the expander while maintaining a gap between the plurality of semiconductor chips;
a squeegee configured to locally press the wafer after the expander expands the sheet member to divide the wafer into the plurality of semiconductor chips; and
a movement mechanism configured to supply the wafer to the expander, at least one of the cooler or the heater, and the squeegee; wherein
the expander, at least one of the cooler or the heater, and the squeegee are linearly aligned in a plan view.
